(19) United States
(12) Patent Application Publication
(10) Pub. No.: US 2026/0013362 A1
(43) Pub. Date: Jan. 8, 2026

(54) DISPLAY DEVICE INCLUDING SHAPED COLOR FILTERS AND ELECTRONIC DEVICE INCLUDING THE SAME

(71) Applicant: SAMSUNG DISPLAY CO., LTD., YONGIN-SI (KR)

(72) Inventors: Gi Na YOO, Yongin-si (KR); Nari HEO, Yongin-si (KR)

(21) Appl. No.: 19/060,933

(22) Filed: Feb. 24, 2025

(30) Foreign Application Priority Data
Jul. 3, 2024 (KR) 10-2024-0087353

(51) Int. Cl. H10K 59/38; H10K 59/40; H10K 59/80

(52) U.S. Cl. CPC H10K 59/38; H10K 59/8792; H10K 59/40

(57) ABSTRACT

A display device according to an embodiment includes light emitting elements arranged in emission areas of sub-pixels, and color filters arranged on the light emitting elements, and arranged in the emission areas and a non-emission area around the emission areas, wherein at least one of the color filters has a convex cross-sectional shape protruding higher than a height of an edge portion at a central portion disposed in each emission area, and at least two of the color filters have different cross-sectional shapes.

### CROSS-REFERENCE TO RELATED APPLICATION

This application claims priority under 35 U.S.C. 119 from Korean Patent Application No. 10-2024-0087353 filed on Jul. 3, 2024, in the Korean Intellectual Property Office, the disclosure of which is herein incorporated by reference in its entirety.

### BACKGROUND

### 1. Technical Field

Embodiments of the present disclosure relate to a display device and an electronic device including the same, and more particularly to a display device including shaped color filters and an electronic device including the same.

### 2. Discussion of Related Art

As information-based societies have developed, various demands have emerged for display devices capable of displaying images. Accordingly, various types of display devices are being developed, such as liquid crystal displays (LCD), plasma display panels (PDP), and organic light-emitting displays (OLED).

### SUMMARY

Aspects of the present disclosure provide a display device capable of improving a side luminance ratio and a viewing angle, and an electronic device including the display device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including light emitting elements arranged in emission areas of sub-pixels, and color filters disposed on the light emitting elements, and overlapping the emission areas and a non-emission area around the emission areas, wherein a first color filter of the color filters has a convex cross-sectional shape including a central portion disposed in its emission area and an edge portion, the central portion protruding higher than a height of the edge portion, and at least two of the color filters have different cross-sectional shapes.

In an embodiment, a second color filter among the color filters may have a concave cross-sectional shape including a central portion disposed in its emission area and an edge portion, the central portion having a height lower than a height of the edge portion.

In an embodiment, the display device may further include a light transmitting pattern disposed on a light emitting element layer including the light emitting elements and disposed under the first color filter.

In an embodiment, the first color filter may have a cross-sectional shape corresponding to the light transmitting pattern, and the central portion of the first color filter may overlap the light transmitting pattern.

In an embodiment, in at least two of the emission areas, thicknesses of the light transmitting pattern may be different.

In an embodiment, a first emission area of the emission areas may include a light transmitting pattern disposed under the first color filter, and a second emission area of the emission areas may include a second color filter disposed in an opening of the light transmitting pattern.

In an embodiment, a color filter disposed in an emission area corresponding to an opening in the light transmitting pattern among the emission areas may have a concave cross-sectional shape in which a height of a central portion disposed in each emission area is lower than a height of an edge portion.

In an embodiment, the emission areas may include a first emission area in which a first light emitting element emitting light of a first color and a first color filter transmitting the light of the first color are disposed, a second emission area in which a second light emitting element emitting light of a second color and a second color filter transmitting the light of the second color are disposed, and a third emission area in which a third light emitting element emitting light of a third color is disposed.

In an embodiment, a size of the second emission area may be smaller than a size of each of the first emission area and the third emission area.

In an embodiment, a light transmitting pattern may be disposed under the second color filter in the second emission area, and the second color filter may have a convex cross-sectional shape corresponding to the light transmitting pattern.

In an embodiment, the light transmitting pattern may include a first pattern disposed under the first color filter in the first emission area and a second pattern disposed under the second color filter in the second emission area, and the first color filter and the second color filter each may have a convex cross-sectional shape corresponding to the first pattern and the second pattern.

In an embodiment, a thickness of the first pattern may be less than a thickness of the second pattern.

In an embodiment, a third color filter may be disposed in the third emission area and transmitting the light of the third color, the light transmitting pattern may further include a third pattern disposed under the third color filter in the third emission area, and the third color filter may have a convex cross-sectional shape corresponding to the third pattern.

In an embodiment, at least two of the first pattern, the second pattern and the third pattern may have different thicknesses.

In an embodiment, a third color filter may be disposed in the third emission area and transmitting the light of the third color, and the light transmitting pattern may including an opening in the third emission area, and the third color filter may have a concave cross-sectional shape in which a height of a central portion disposed in the third emission area is lower than a height of an edge portion.

In an embodiment, the display device may further include a touch sensing layer including a touch electrode and an insulating layer, and the touch sensing layer may be disposed between a first color filter layer including the color filters and the light emitting element layer.

In an embodiment, the light transmitting pattern may be integral with the insulating layer, and the insulating layer may partially protrude under the first color filter to form the light transmitting pattern.

In an embodiment, the first color filter may include a lower layer portion disposed in an emission area of the emission areas and a non-emission area surrounding the emission area, and an upper layer portion disposed on a portion of the lower layer portion in the emission area and protruding in a height direction from the lower layer portion.

In an embodiment, the display device may further include a light blocking layer disposed in the non-emission area on a light emitting element layer including the light emitting elements, and the upper layer portion of the first color filter may be surrounded by the light blocking layer and spaced apart from the light blocking layer in plan view.

According to an aspect of the present disclosure, there is provided a display device including light emitting elements arranged in emission areas of sub-pixels, and color filters disposed on the light emitting elements, and overlapping the emission areas and a non-emission area around the emission areas, wherein a first color filter of the color filters has a convex cross-sectional shape including a central portion disposed as an island its emission area and an edge portion surrounding the central portion, the central portion having a sidewall facing a sidewall of the edge portion, and at least two of the color filters have different cross-sectional shapes.

According to an aspect of the present disclosure, there is provided an electronic device including a display device, the display device including light emitting elements arranged in emission areas of sub-pixels, and color filters disposed on the light emitting elements, and overlapping the emission areas and a non-emission area around the emission areas, wherein a first color filter of the color filters may have a convex cross-sectional shape including a central portion disposed in its emission area and an edge portion, the central portion protruding higher than a height of the edge portion, and at least two of the color filters have different cross-sectional shapes.

According to embodiments, the color filter of at least one sub-pixel among sub-pixels forming a pixel may be formed in a convex shape. Accordingly, the side luminance ratio and the viewing angle of the pixel, and the display device including the same may be improved.

According to some embodiments, at least two color filters among color filters of sub-pixels may be formed to have different cross-sectional shapes. Accordingly, the side color of the pixel and the display device including the same may be adjusted or improved.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing an electronic device according to an embodiment;

FIG. 2 is a perspective view illustrating a display device included in an electronic device according to an embodiment;

FIG. 3 is a cross-sectional view of the display device of FIG. 2 viewed from the side;

FIG. 4 is a plan view illustrating a pixel of a display device according to an embodiment;

FIG. 5 is a cross-sectional view illustrating a display device according to an embodiment;

FIG. 6 is a cross-sectional view showing a display device according to an embodiment;

FIG. 7 is a cross-sectional view showing a display device according to an embodiment;

FIG. 8 is a cross-sectional view showing a display device according to an embodiment;

FIG. 9 is a cross-sectional view illustrating a display device according to an embodiment;

FIG. 10 is a cross-sectional view showing a display device according to an embodiment;

FIG. 11 is a cross-sectional view showing a display device according to an embodiment;

FIG. 12 is a plan view illustrating a pixel of a display device according to an embodiment;

FIG. 13 is a cross-sectional view showing a display device according to an embodiment; and

FIG. 14 is a cross-sectional view illustrating a display device according to an embodiment.

### DETAILED DESCRIPTION

The present invention will now be described more fully hereinafter with reference to the accompanying drawings, in which embodiments of the disclosure are shown. Aspects of this disclosure may, however, be embodied in different forms and should not be construed as limited to embodiments set forth herein. Rather, embodiments are provided so that this disclosure will be thorough and complete, and will fully convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification. In the attached figures, the thickness of layers and regions may be exaggerated for clarity.

It will be understood that, although the terms “first,” “second,” etc. may be used herein to describe various elements, these elements should not be limited by these terms. These terms are used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Aspects of the present disclosure may provide a display device capable of improving a side luminance ratio and a viewing angle, and an electronic device including the display device. Aspects of the present disclosure may provide a pixel including color filters arranged on respective light emitting elements, and the color filters may have cross-sectional shapes configured to increase side light emitted from an emission area, reducing a difference between front luminance and the side luminance, and increasing a viewing angle of the pixel. For example, a color filter transmission length of at least a portion of the side light may be reduced or minimized in the pixel. Accordingly, a difference between the color filter transmission length of front light and the color filter transmission length of the side light may be reduced, and the side luminance ratio may be improved (e.g., increased).

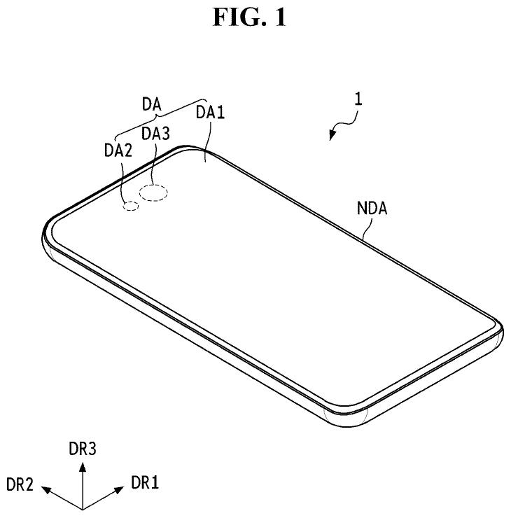

FIG. 1 is a perspective view showing an electronic device according to an embodiment.

Referring to FIG. 1, an electronic device 1 is configured to display a moving image or a still image. The electronic device 1 may refer to any electronic device providing a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder or the like, which provide a display screen.

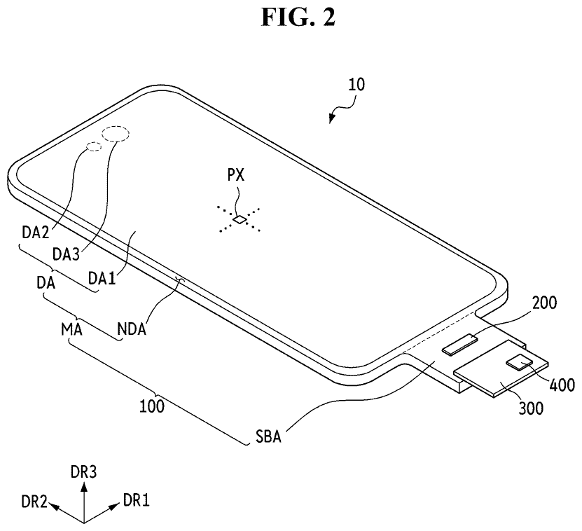

The electronic device 1 may include a display device (e.g., a display device 10 of FIG. 2) providing a display screen. In an embodiment, the display device may be a light emitting display device including a light emitting element such as an inorganic light emitting diode or an organic light emitting diode, but is not limited thereto. Although a light emitting display device including an organic light emitting diode is described as a display device to which embodiments may be applied, devices or fields to which embodiments may be applied are not limited thereto. For example, embodiments may also be applied to other types of display devices.

The shape of the electronic device 1 may be variously provided. For example, the electronic device 1 may have a shape such as a rectangular shape elongated in a horizontal direction, a rectangular shape elongated in a vertical direction, a square shape, a substantially quadrilateral shape with rounded corners, other polygonal shapes or a circular shape. In an embodiment, the shape of a display area DA of the electronic device 1 may be similar to the overall shape of the electronic device 1, but is not limited thereto. In FIG. 1, the electronic device 1 having a rectangular shape that may be longer in a second direction DR2 than in a first direction DR1 is exemplified.

The electronic device 1 may include the display area DA and a non-display area NDA. The display area DA may be an area where an image can be displayed, and the non-display area NDA may be an area where an image is not displayed. The display area DA may also be referred to as an active region, and the non-display area NDA may also be referred to as a non-active region. The display area DA may substantially occupy the center of the electronic device 1.

The display area DA may include a first display area DA1, a second display area DA2, and a third display area DA3. The second display area DA2 and the third display area DA3 may be areas in which components for adding various functions to the electronic device 1 are disposed, and the second display area DA2 and the third display area DA3 may correspond to a component area. Although FIG. 1 shows an embodiment in which the electronic device 1 includes two component areas, the number or location of the component areas is not limited. The first display area DA1 may be an area of the display area DA where no component is disposed.

FIG. 2 is a perspective view illustrating a display device included in an electronic device according to an embodiment.

Referring to FIG. 1 and FIG. 2, the electronic device 1 according to an embodiment may include the display device 10. The display device 10 may provide a screen of the electronic device 1. The display device 10 may have a planar shape similar to the shape of the electronic device 1. For example, the display device 10 may have a shape similar to a rectangular shape having a short side in the first direction DR1 and a long side in the second direction DR2. The edge where the short side in the first direction DR1 and the long side in the second direction DR2 meet may be rounded, but is not limited thereto and may be formed at a right angle. The planar shape of the display device 10 is not limited to a quadrilateral shape, and may have another polygonal shape, a circular shape, an elliptical shape, or another shape.

The display device 10 may include a display panel 100, a display driver 200, a circuit board 300, and a touch driver 400.

The display panel 100 may include a main region MA and a sub-region SBA.

The main region MA may include the display area DA including pixels PX configured to display an image and the non-display area NDA disposed around at least a portion of the display area DA. The display area DA may be disposed in a center portion of the main region MA, and the non-display area NDA may surround the display area DA.

The display area DA may include the first display area DA1, the second display area DA2, and the third display area DA3. The display area DA may include emission areas of the pixels PX, and light may be emitted from the emission areas.

Each pixel PX may include a plurality of sub-pixels that emit light. For example, each pixel PX may include a plurality of sub-pixels that emit light of different colors. Each sub-pixel may include a light emitting element disposed in each emission area.

The display panel 100 may include light emitting elements and pixel circuits (e.g., pixel circuits including transistors and capacitors) of the pixels PX, and a pixel defining film surrounding the emission areas of the pixels PX. The light emitting elements of the pixels PX may be disposed in the emission areas of the corresponding pixels PX. In an embodiment, each light emitting element may include one of an organic light emitting diode (LED) including an organic light emitting layer, a quantum dot LED including a quantum dot light emitting layer, an inorganic LED including an inorganic semiconductor, or an ultra-small light emitting diode such as a micro LED or nano LED, but is not limited thereto.

The non-display area NDA may be an area outside the display area DA. The non-display area NDA may be an edge area of the main region MA of the display panel 100. In an embodiment, the non-display area NDA may include a gate driver that supplies gate signals to the gate lines, and fan-out lines that connect the display driver 200 to the display area DA.

The sub-region SBA may be a region extending from one side of the main region MA. The sub-region SBA may include a flexible material which can be bent, folded or rolled. For example, when the sub-region SBA is bent (or folded), the sub-region SBA may overlap the main region MA in a thickness direction (e.g., a third direction DR3). For example, when the display device 10 is bent in the sub-region SBA, at least a portion of the sub-region SBA including an area where the display driver 200 is disposed and an area where a pad portion connected to the circuit board 300 is disposed may be disposed under the main region MA.

The sub-region SBA may include the display driver 200 and a pad portion connected to the circuit board 300. In another embodiment, the sub-region SBA may be omitted, and the display driver 200 and the pad portion may be disposed in the non-display area NDA. In another embodiment, the display driver 200 may be disposed on the circuit board 300 connected to the display panel 100, and may be electrically connected to the display panel 100 through the pad portion.

The display driver 200 may output driving signals and driving voltages for driving the display panel 100. For example, the display driver 200 may supply data voltages to data lines, supply driving voltages (e.g., first pixel voltage (or anode voltage) and second pixel voltage (or cathode voltage)) to power lines, and supply gate control signals to the gate driver. In an embodiment, the display driver 200 may be formed as an integrated circuit (IC) and mounted on the display panel 100 by a chip on glass (COG) method, a chip on plastic (COP) method, or an ultrasonic bonding method.

The circuit board 300 may be attached to the pad portion of the display panel 100 by using an anisotropic conductive film (ACF) or the like. Lead lines of the circuit board 300 may be electrically connected to the pad portion of the display panel 100. In an embodiment, the circuit board 300 may be a flexible printed circuit board, a printed circuit board, or a flexible film such as a chip on film.

The touch driver 400 may be mounted on the circuit board 300. The touch driver 400 may be connected to a touch sensing layer of the display panel 100. The touch driver 400 may supply each touch drive signal to touch electrodes of the touch sensing layer, and may sense the amount of change in capacitance formed between the touch electrodes. In an embodiment, the touch driving signal may be a pulse signal having a predetermined frequency. The touch driver 400 may detect whether or not a touch input has occurred and coordinates based on the amount of change in capacitance between the touch electrodes. In an embodiment, the touch driver 400 may be formed as an integrated circuit (IC).

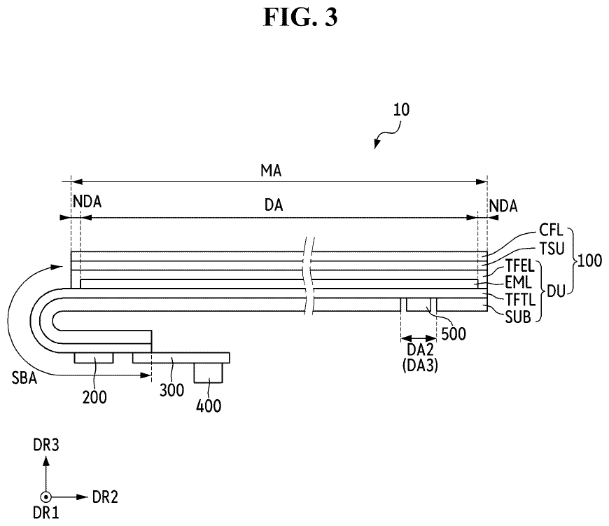

FIG. 3 is a cross-sectional view of the display device of FIG. 2 viewed from the side. FIG. 3 illustrates the sub-region SBA of the display panel 100 in a bent state in the display device 10 of FIG. 2.

Referring to FIG. 3, the display panel 100 may include a display layer DU, a touch sensing layer TSU, and a color filter layer CFL.

The display layer DU may include a substrate SUB, a thin film transistor layer TFTL, a light emitting element layer EML, and an encapsulation layer TFEL.

The substrate SUB may be a base substrate or a base member. The substrate SUB may be a flexible substrate which can be bent, folded or rolled, but is not limited thereto. In an embodiment, the substrate SUB may include a polymer resin such as polyimide (PI). In another embodiment, the substrate SUB may include a glass material or a metal material.

The thin film transistor layer TFTL may be disposed on the substrate SUB. The thin film transistor layer TFTL may include circuit elements, e.g., thin film transistors and capacitors, constituting pixel circuits of the pixels PX. The thin film transistor layer TFTL may further include wires. For example, the thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. In an embodiment, when the display panel 100 includes the gate driver disposed in the non-display area NDA, the thin film transistor layer TFTL may further include circuit elements constituting the gate driver.

The thin film transistor layer TFTL may be disposed in the display area DA, the non-display area NDA, and the sub-region SBA. The circuit elements constituting the pixel circuits of the pixels PX, and the gate lines, the data lines, and the power lines that are electrically connected to the pixels PX may be disposed in the display area DA of the thin film transistor layer TFTL. The gate lines, the data lines, and the power lines may extend to the non-display area NDA of the thin film transistor layer TFTL, and may be respectively electrically connected to the gate driver, the display driver 200, or the pad portion. The gate control lines and the fan-out lines may be disposed in the non-display area NDA of the thin film transistor layer TFTL. The lead lines may be disposed in the sub-region SBA of the thin film transistor layer TFTL.

The light emitting element layer EML may be disposed on the thin film transistor layer TFTL. The light emitting element layer EML may include a pixel defining film that defines emission areas (or light emitting element arrangement areas) of pixels PX, and light emitting elements arranged in the emission areas. In an embodiment, a pixel area where each pixel PX of the display area DA is disposed may include a plurality of emission areas where light emitting elements of sub-pixels forming the corresponding pixel PX are arranged.

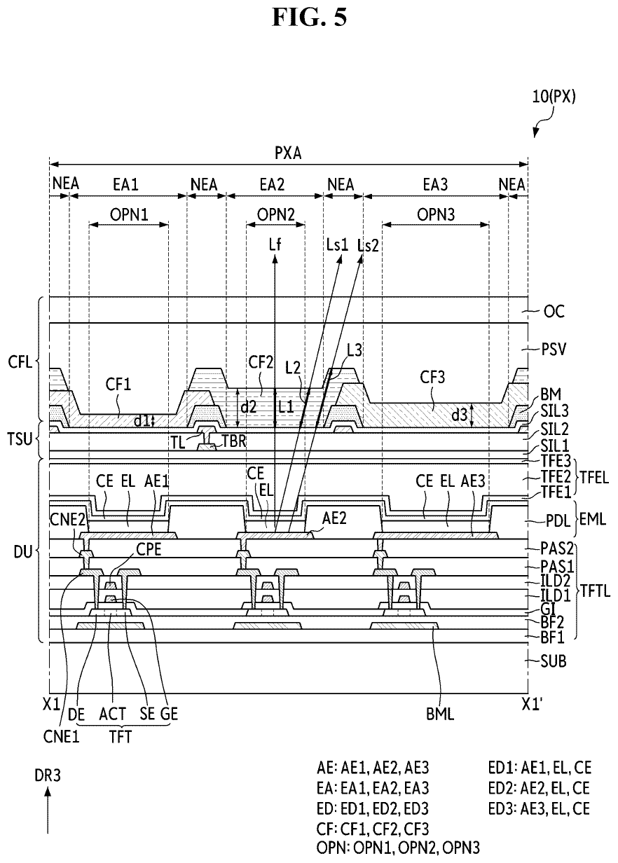

The light emitting element may include a first electrode and a second electrode facing each other, and a light emitting layer interposed between the first electrode and the second electrode. In an embodiment, the first electrode of the light emitting element may correspond to the pixel electrode shown in FIG. 5 and subsequent drawings, and the second electrode of the light emitting element may correspond to the common electrode shown in FIG. 5 and subsequent drawings. In an embodiment, the light emitting element may be an organic light emitting diode including an organic light emitting layer, but is not limited thereto. For example, the light emitting element may be another type of light emitting element, such as a quantum dot light emitting diode including a quantum dot light emitting layer, an inorganic light emitting diode including an inorganic semiconductor, a micro light emitting diode, or a nano light emitting diode. When a first pixel voltage (e.g., anode voltage) is applied to the first electrode of the light emitting element through at least one of the thin film transistors of each pixel circuit, and a second pixel voltage (e.g., cathode voltage) is applied to the second electrode of the light emitting element through the power line, holes and electrons may recombine in the light emitting layer and the light emitting element may emit light.

The encapsulation layer TFEL may be disposed on the light emitting element layer EML. For example, the encapsulation layer TFEL may cover the top surface and the side surface of the light emitting element layer EML, and may protect the light emitting element layer EML. In an embodiment, the encapsulation layer TFEL may include at least one inorganic film and at least one organic film for encapsulating the light emitting element layer EML. For example, the encapsulation layer TFEL may include a plurality of inorganic encapsulation layers and an organic encapsulation layer interposed between the inorganic encapsulation layers.

The touch sensing layer TSU may be disposed on the display layer DU. For example, the touch sensing layer TSU may be disposed or formed on the encapsulation layer TFEL, or the touch sensing layer TSU may be disposed on a separate substrate disposed on the display layer DU.

The touch sensing layer TSU may include touch electrodes for sensing the user's touch input, and wires that electrically connect the touch electrodes to the touch driver 400. In an embodiment, the touch sensing layer TSU may sense the user's touch in a mutual capacitance manner or a self-capacitance manner, and the touch electrodes may have a shape for constituting a mutual capacitance type or self-capacitance type touch sensor. For example, the touch electrodes may include driving electrodes and sensing electrodes extending and/or connected in different directions to constitute a mutual capacitance type touch sensor, or may include touch electrodes disposed at points corresponding to respective touch nodes or coordinates to constitute a self-capacitance type touch sensor.

The touch electrodes of the touch sensing layer TSU may be disposed in a touch sensor area overlapping the display area DA. The area in the display area DA where the touch electrodes are disposed may be the touch sensor area. For example, the touch sensor area may be all or a portion of the display area DA. Wires electrically connected to the touch electrodes of the touch sensing layer TSU may be disposed in a peripheral area overlapping the non-display area NDA.

The color filter layer CFL may be disposed on the touch sensing layer TSU. The color filter layer CFL may include color filters arranged in the respective emission areas of the pixels PX. For example, the color filter layer CFL may include color filters of different colors that are arranged on the light emitting elements of the sub-pixels forming each pixel PX and selectively transmit light of a color or wavelength corresponding to each sub-pixel. Each of the color filters may selectively transmit light of a specific color or wavelength and may block or absorb light of a different color or wavelength.

In an embodiment, the color filter layer CFL may further include a light blocking layer. The light blocking layer may be disposed in a non-emission area surrounding the emission areas of the pixels PX. The light blocking layer may be formed separately from the color filters by using a separate light blocking material, or may be formed by overlapping a plurality of color filters that selectively transmit light of different wavelengths.

The color filter layer CFL may absorb a portion of light coming from the outside of the display device 10 to reduce reflected light due to external light. Color distortion caused by reflection of the external light may be inhibited or prevented by the color filter layer CFL.

In an embodiment, the color filter layer CFL may be disposed directly on the touch sensing layer TSU (or display layer DU). Accordingly, the display device 10 may not include a separate substrate for the color filter layer CFL, and may have a further reduced thickness.

In some embodiments, the display device 10 may further includes an optical device 500 disposed in a component area (e.g., the second display area DA2 or the third display area DA3 of FIG. 1 and FIG. 2). The optical device 500 may emit or receive light in infrared, ultraviolet, and visible light bands. For example, the optical device 500 may be an optical sensor that detects light incident on the display device 10 such as a proximity sensor, an illuminance sensor, and a camera sensor or an image sensor.

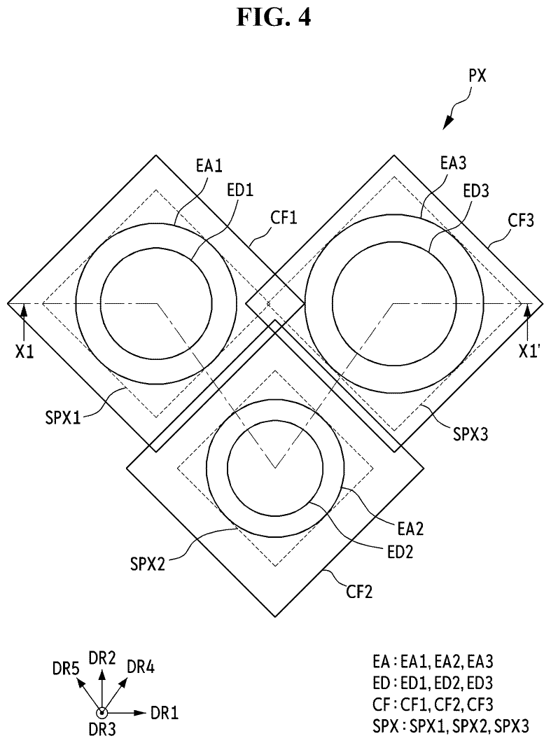

FIG. 4 is a plan view illustrating a pixel of a display device according to an embodiment. For example, FIG. 4 shows substantial shapes or positions of emission areas EA of the pixel PX according to an embodiment, and light emitting elements ED and color filters CF arranged in the emission areas EA.

Referring to FIG. 4, the pixel PX may include sub-pixels SPX including the respective emission areas EA. For example, the pixel PX may include a first sub-pixel SPX1 including a first emission area EA1 emitting light of a first color, a second sub-pixel SPX2 including a second emission area EA2 emitting light of a second color, and a third sub-pixel SPX3 including a third emission area EA3 emitting light of a third color. In an embodiment, each pixel PX may include one first sub-pixel SPX1, one second sub-pixel SPX2, and one third sub-pixel SPX3, but embodiments are not limited thereto. For example, a pixel PX according to another embodiment may include one first sub-pixel SPX1, two second sub-pixels SPX2, and one third sub-pixel SPX3. In addition, the type, number, ratio, and/or combination of the sub-pixels SPX constituting the pixel PX may vary depending on embodiments.

In an embodiment, the first sub-pixel SPX1, the second sub-pixel SPX2, and the third sub-pixel SPX3 may be a red sub-pixel emitting red light, a green sub-pixel emitting green light, and a blue sub-pixel emitting blue light, respectively. However, embodiments are not limited thereto, and the color or wavelength of light emitted from each sub-pixel SPX may vary depending on embodiments.

FIG. 4 illustrates an embodiment in which each pixel PX includes the first sub-pixel SPX1, the second sub-pixel SPX2, and the third sub-pixel SPX3, and the first sub-pixel SPX1, the second sub-pixel SPX2, and the third sub-pixel SPX3 are arranged in a substantially inverted-delta shape in plan view. For example, the first sub-pixel SPX1 and the second sub-pixel SPX2 may be adjacent in a fifth direction DR5 tilted with respect to the first direction DR1 and the second direction DR2, the second sub-pixel SPX2 and the third sub-pixel SPX3 may be adjacent in a fourth direction DR4 between the first direction DR1 and the second direction DR2, and the first sub-pixel SPX1 and the third sub-pixel SPX3 may be adjacent substantially in the first direction DR1. However, embodiments are not limited thereto, and the arrangement pattern of the sub-pixels SPX and the pixels PX including the same may be variously changed according to embodiments.

Each sub-pixel SPX may include the light emitting element ED disposed in each emission area EA. For example, the first sub-pixel SPX1 may include a first light emitting element ED1 disposed in the first emission area EA1, the second sub-pixel SPX2 may include a second light emitting element ED2 disposed in the second emission area EA2, and the third sub-pixel SPX3 may include a third light emitting element ED3 disposed in the third emission area EA3. The light emitting elements ED may be arranged in the display layer DU of FIG. 3. For example, the light emitting elements ED may be disposed in the light emitting element layer EML of FIG. 3.

In an embodiment, each sub-pixel SPX may further include a pixel circuit that is electrically connected to each light emitting element ED and controls driving of the light emitting element ED. For example, the first sub-pixel SPX1 may include the first light emitting element ED1 and a first pixel circuit electrically connected to the first light emitting element ED1, the second sub-pixel SPX2 may include the second light emitting element ED2 and a second pixel circuit electrically connected to the second light emitting element ED2, and the third sub-pixel SPX3 may include the third light emitting element ED3 and a third pixel circuit electrically connected to the third light emitting element ED3.

In an embodiment, the first light emitting element ED1, the second light emitting element ED2, and the third light emitting element ED3 may emit light of the first color, light of the second color, and light of the third color, respectively. For example, the first light emitting element ED1, the second light emitting element ED2, and the third light emitting element ED3 may be light emitting elements of different colors that emit red light, green light, and blue light, respectively. However, the embodiments are not limited thereto. For example, in another embodiment, the first light emitting element ED1, the second light emitting element ED2, and the third light emitting element ED3 may emit light of the same color, and a light converting layer for converting a color or wavelength of light may be disposed above at least one of the first light emitting element ED1, the second light emitting element ED2, or the third light emitting element ED3 to change or control the color of light emitted from each sub-pixel SPX. For example, the light converting layer may include quantum dot layers that convert the light (e.g., the blue light) emitted from the light emitting element ED into different colors of light.

In FIG. 4, a light transmitting area where each light emitting element ED is disposed and light generated from the light emitting element ED is emitted may be defined as the emission area EA of each sub-pixel SPX. For example, the emission area EA of each sub-pixel SPX may include a light emitting element area where the light emitting layer of the light emitting element ED is disposed on the pixel electrode of each sub-pixel SPX exposed by an opening of a pixel defining film. Further, the emission area EA of each sub-pixel SPX, which is an area surrounded by the light blocking layer disposed on the light emitting element layer including the light emitting elements ED, may be an area corresponding to each opening of the light blocking layer.

In an embodiment, the sizes (e.g., emission areas) of the first emission area EA1, the second emission area EA2, and the third emission area EA3 may be different from each other. For example, the size of the first emission area EA1 may be greater than the size of the second emission area EA2 and may be less than the size of the third emission area EA3. In an embodiment, the first light emitting element ED1, the second light emitting element ED2, and the third light emitting element ED3 may have sizes (e.g., areas) corresponding to the sizes of the first emission area EA1, the second emission area EA2, and the third emission area EA3, respectively. For example, the size of the first light emitting element ED1 may be larger than the size of the second light emitting element ED2, and may be smaller than the size of the third light emitting element ED3. Depending on the size of each light emitting element ED and the emission area EA including the same, the intensity or luminance of light emitted from each emission area EA may vary.

In FIG. 4, the position or size of each sub-pixel SPX is shown with respect to each emission area EA, but embodiments are not limited thereto. For example, the positions or sizes of pixel circuit areas where pixel circuits of the sub-pixels SPX are arranged may be substantially the same.

By controlling the sizes or ratios of the light emitting elements ED included in the pixel PX and the emission areas EA including the same, the color of the light emitted from the pixel PX may be controlled, and the color of the screen displayed on the display device 10 may be controlled. Further, the sizes of the light emitting elements ED and the emission areas EA may be appropriately adjusted in consideration of the lifespan of the light emitting elements ED or the like. For example, the sizes of the light emitting elements ED and the emission areas EA may be related to the light efficiency or the lifespan of the light emitting elements ED, which may be in a trade-off relationship with reflection by external light. The sizes of the light emitting elements ED and the emission areas EA may be appropriately adjusted in consideration of factors including light efficiency, device lifespan, and reflection.

The non-emission area, which is the remaining area of the display area DA excluding the emission areas EA of the sub-pixels SPX, may correspond to a light blocking area. For example, the display area DA may include the emission areas EA of the pixels PX and the non-emission area surrounding the emission areas EA. For example, the non-emission area, which is a peripheral area disposed around each of the emission areas EA and between the emission areas EA, may be an area blocked by the light blocking layer. Each pixel PX may include the emission areas EA and the non-emission area around the emission areas EA, and each emission area EA may be surrounded by a portion of the non-emission area.

Each color filter CF may be disposed in the emission areas EA of the sub-pixels SPX. For example, a first color filter CF1, a second color filter CF2, and a third color filter CF3 may be arranged in the first emission area EA1, the second emission area EA2, and the third emission area EA3, respectively.

In an embodiment, each color filter CF may be further disposed in the non-emission area around each emission area EA. For example, each color filter CF may include a central portion disposed in each emission area EA and an edge portion disposed around the emission area EA. For example, the edge portion of each color filter CF may be a portion overlapping the non-emission area NEA. For example, the first color filter CF1 may include a central portion disposed in the first emission area EA1 and an edge portion disposed in a portion of the non-emission area NEA disposed directly around the first emission area EA1 and surrounding the first emission area EA1. Similarly, the second color filter CF2 may include a central portion disposed in the second emission area EA2 and an edge portion disposed in a portion of the non-emission area NEA disposed directly around the second emission area EA2 and surrounding the second emission area EA2, and the third color filter CF3 may include a central portion disposed in the third emission area EA3 and an edge portion disposed in a portion of the non-emission area NEA disposed directly around the third emission area EA3 and surrounding the third emission area EA3.

In an embodiment, each color filter CF may overlap at least one adjacent color filter CF in the non-emission area. For example, each color filter CF may overlap at least one color filter CF disposed in the emission area EA of an adjacent pixel PX or an adjacent sub-pixel SPX. Although FIG. 4 illustrates an embodiment in which the color filters CF arranged in one pixel PX overlap each other in the non-emission area of the corresponding pixel, the color filters CF may also overlap the color filters CF of the adjacent pixel PX.

Further, FIG. 4 illustrates an embodiment in which the color filters CF are formed as individual patterns corresponding to each emission area EA, but embodiments are not limited thereto. For example, in another embodiment, the first color filter CF1 may include openings disposed entirely in the non-emission area as well as the first emission areas EA1 of the first sub-pixels SPX1 disposed in the display area DA and corresponding to the second emission areas EA2 and the third emission areas EA3 of the display area DA. Similarly, the second color filter CF2 may include openings disposed entirely in the non-emission area as well as the second emission areas EA2 of the second sub-pixels SPX2 disposed in the display area DA and corresponding to the first emission areas EA1 and the third emission areas EA3 of the display area DA, and the third color filter CF3 may include openings disposed entirely in the non-emission area as well as the third emission areas EA3 of the third sub-pixels SPX3 disposed in the display area DA and corresponding to the first emission areas EA1 and the second emission areas EA2 of the display area DA. For example, the color filters CF may be formed as individual patterns corresponding to the respective emission areas EA, or may be formed entirely in the display area DA.

FIG. 5 is a cross-sectional view illustrating a display device according to an embodiment. For example, FIG. 5 shows a portion of the display device 10 corresponding to a cross section of the pixel PX along line XI-X1′ of FIG. 4. As an example, FIG. 5 shows a portion of the display panel 100 corresponding to a portion of a pixel area PXA where the pixel PX of FIG. 4 is disposed.

Referring to FIGS. 1 to 5, the display device 10 according to an embodiment may include the display layer DU, the touch sensing layer TSU, and the color filter layer CFL. The display layer DU may include the substrate SUB, the thin film transistor layer TFTL, the light emitting element layer EML, and the encapsulation layer TFEL. The touch sensing layer TSU may include a touch electrode TL and a bridge pattern TBR. The color filter layer CFL may include a light blocking layer BM and the color filters CF.

The substrate SUB may be a base substrate or a base member. In an embodiment, the substrate SUB may be a flexible substrate which can be bent, folded or rolled, but is not limited thereto.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PASI, a second connection electrode CNE2, and a second passivation layer PAS2. However, embodiments are not limited thereto, and the number or type of conductive layers and insulating layers forming the thin film transistor layer TFTL, and/or the structure or type of the thin film transistor TFT may be variously provided.

The first buffer layer BFI may be disposed on the substrate SUB. In an embodiment, the first buffer layer BF1 may include an inorganic film capable of inhibiting or preventing penetration of air or moisture.

The lower metal layer BML may be disposed on the first buffer layer BF1. In an embodiment, the lower metal layer BML may be formed as a single layer or multiple layers made of any one of molybdenum (Mo), aluminum (Al), chromium (Cr), gold (Au), titanium (Ti), nickel (Ni), neodymium (Nd) or copper (Cu), or an alloy thereof.

The second buffer layer BF2 may cover the first buffer layer BF1 and the lower metal layer BML. In an embodiment, the second buffer layer BF2 may include an inorganic film capable of inhibiting or preventing penetration of air or moisture.

The thin film transistor TFT may be disposed on the second buffer layer BF2. A thin film transistor TFT may be disposed at each of the pixel circuits (e.g., pixel circuits of the sub-pixels SPX) included in each pixel PX. FIG. 5 shows the approximate shape of an example thin film transistor TFT (e.g., the thin film transistor TFT electrically connected to the first light emitting element ED1, the second light emitting element ED2, or the third light emitting element ED3) among the thin film transistors TFT that may be provided in the pixel circuit of each sub-pixel SPX. Each thin film transistor TFT shown in FIG. 5 may be a switching transistor or a driving transistor constituting each pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction, and may be insulated from the gate electrode GE by the gate insulating layer GI. Portions of the semiconductor layer ACT may be conductive and may form the source electrode SE (or source region) and the drain electrode DE (or drain region). For example, portions of the semiconductor layer ACT may be doped to form the source electrode SE and the drain electrode DE.

The gate electrode GE may be disposed on the gate insulating layer GI. The gate electrode GE may overlap the semiconductor layer ACT with the gate insulating layer GI interposed therebetween.

The gate insulating layer GI may be disposed on the semiconductor layer ACT. For example, the gate insulating layer GI may cover the semiconductor layer ACT and the second buffer layer BF2, and may be disposed between the semiconductor layer ACT and the gate electrode GE. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be overlap the contact hole of the gate insulating layer GI and the contact hole of the second interlayer insulating layer ILD2 in the thickness direction.

The capacitor electrode CPE may be disposed on the first interlayer insulating layer ILD1. The capacitor electrode CPE may overlap the gate electrode GE in the thickness direction. The capacitor electrode CPE and the gate electrode GE may form a capacitance. For example, a storage capacitor of each pixel circuit may be formed by the capacitor electrode CPE and the gate electrode GE.

The second interlayer insulating layer ILD2 may cover the capacitor electrode CPE and the first interlayer insulating layer ILD1. The second interlayer insulating layer ILD2 may include a contact hole through which the first connection electrode CNEI passes. The contact hole of the second interlayer insulating layer ILD2 may be connected to the contact hole of the first interlayer insulating layer ILD1 and the contact hole of the gate insulating layer GI.

An upper portion of the first connection electrode CNE1 may be disposed on the second interlayer insulating layer ILD2. The first connection electrode CNE1 may electrically connect the drain electrode DE of the thin film transistor TFT to the second connection electrode CNE2. When the type of the thin film transistor TFT and/or the structure of the pixel circuit is changed, the first connection electrode CNEI may electrically connect the source electrode SE of the thin film transistor TFT to the second connection electrode CNE2. The first connection electrode CNE1 may be in contact with and/or connected to the drain electrode DE of the thin film transistor TFT through a contact hole formed in the second interlayer insulating layer ILD2, the first interlayer insulating layer ILD1, and the gate insulating layer GI.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 to a pixel electrode AE of the light emitting element ED. The second connection electrode CNE2 may be in contact with and/or connected to the first connection electrode CNE1 through a contact hole formed in the first passivation layer PAS1. Further, the second connection electrode CNE2 may be in contact with and/or connected to the pixel electrode AE of the light emitting element ED through a contact hole formed in the second passivation layer PAS2. In another embodiment, the thin film transistor layer TFTL may not include the second connection electrode CNE2, and the pixel electrode AE of the light emitting element ED may be directly connected to the first connection electrode CNE1 (or one electrode of the thin film transistor TFT).

The second passivation layer PAS2 may cover the second connection electrode CNE2 and the first passivation layer PAS1. The second passivation layer PAS2 may include a contact hole through which the pixel electrode AE of the light emitting element ED passes. In another embodiment, the thin film transistor layer TFTL may not include the second connection electrode CNE2 and the second passivation layer PAS2, and the pixel electrode AE of the light emitting element ED may be disposed on the first passivation layer PAS1.

The light emitting element layer EML may be disposed on the thin film transistor layer TFTL. The light emitting element layer EML may include the light emitting elements ED and the pixel defining film PDL. The light emitting elements ED may be disposed in the respective emission areas EA.

Each light emitting element ED may include the pixel electrode AE (e.g., the first electrode or the anode electrode of the light emitting element ED), the light emitting layer EL, and the common electrode CE (e.g., the second electrode or the cathode electrode of the light emitting element ED). For example, the first light emitting element ED1 disposed in each first emission area EA1 may include the first pixel electrode AE1, and the light emitting layer EL and the common electrode CE. The first pixel electrode AE1, and the light emitting layer EL and the common electrode CE may be sequentially disposed on the first pixel electrode AE1. The second light emitting element ED2 disposed in each second emission area EA2 may include the second pixel electrode AE2, and the light emitting layer EL and the common electrode CE. The second pixel electrode AE2, and the light emitting layer EL and the common electrode CE may be sequentially disposed on the second pixel electrode AE2. The third light emitting element ED3 disposed in each third emission area EA3 may include the third pixel electrode AE3, and the light emitting layer EL and the common electrode CE. The third pixel electrode AE3, and the light emitting layer EL and the common electrode CE may be sequentially disposed on the third pixel electrode AE3.

The pixel electrode AE may be disposed on the second passivation layer PAS2. Different pixel electrodes AE may be disposed in different emission areas EA. For example, the first pixel electrode AE1, the second pixel electrode AE2, and the third pixel electrode AE3 of the pixel PX may be disposed in the first emission area EA1, the second emission area EA2, and the third emission area EA3 of the pixel PX, respectively.

In an embodiment, at least a portion of each of the pixel electrodes AE may be exposed without being covered by the pixel defining film PDL. For example, at least a portion of the area of each first pixel electrode AEl that includes the central portion thereof may be exposed by a first opening OPN1 of the pixel defining film PDL, at least a portion of the area of each second pixel electrode AE2 that includes the central portion thereof may be exposed by a second opening OPN2 of the pixel defining film PDL, and at least a portion the area of each third pixel electrode AE3 that includes the central portion thereof may be exposed by a third opening OPN3 of the pixel defining film PDL. The edge portions of the pixel electrodes AE may be covered by the pixel defining film PDL.

The respective light emitting layers EL may be arranged on a portion of the pixel electrodes AE exposed by the openings OPN of the pixel defining film PDL. Accordingly, each light emitting element ED may be disposed and/or formed in each emission area EA. In an embodiment, each light emitting layer EL and the light emitting element ED including the same may have a size and/or shape corresponding to that of each opening OPN of the pixel defining film PDL.

The pixel electrode AE may be electrically connected to one electrode of the thin film transistor TFT. For example, the pixel electrode AE may be electrically connected to the drain electrode DE of the thin film transistor TFT through the first connection electrode CNE1 and the second connection electrode CNE2.

The light emitting layer EL may be disposed on the pixel electrode AE. In an embodiment, the light emitting layer EL may be an organic light emitting layer made of an organic material, but is not limited thereto.

In an embodiment, the light emitting layers EL of the first light emitting element ED1, the second light emitting element ED2, and the third light emitting element ED3 may emit light of different colors. For example, the light emitting layer EL of the first light emitting element ED1 may emit light of the first color, e.g., red light, the light emitting layer EL of the second light emitting element ED2 may emit light of the second color, e.g., green light, and the light emitting layer EL of the third light emitting element ED3 may emit light of the third color, e.g., blue light.

However, the embodiments are not limited thereto. For example, in another embodiment, the light emitting layer EL of the light emitting elements ED may be formed as a common layer disposed on the different pixel electrodes AE and the pixel defining film PDL, and the light emitting layer EL disposed on different pixel electrodes AE may emit light of the same color. In this case, the display device 10 may further include a color adjustment layer (e.g., color conversion layer including wavelength conversion patterns and/or color adjustment layer including the color filters CF) disposed on the light emitting elements ED.

The common electrode CE may be disposed on the light emitting layer EL of each of the light emitting elements ED. In an embodiment, the common electrode CE may be formed as one common layer disposed entirely in the display area DA, and the light emitting elements ED of the pixels PX may share one common electrode CE. The common electrode CE may receive a common voltage (e.g., second pixel voltage or cathode voltage).

The pixel defining film PDL may include the openings OPN corresponding to the emission areas EA and may be disposed on a portion of the pixel electrodes AE and the second passivation layer PAS2. For example, the pixel defining film PDL may be disposed at least in the non-emission area NEA, and may include the first opening OPN1 disposed in each first emission area EA1, the second opening OPN2 disposed in each second emission area EA2, and the third opening OPN3 disposed in each third emission area EA3.

In an embodiment, the openings OPN of the pixel defining film PDL may have a size smaller than that of each of the emission areas EA, and may be disposed in the emission areas EA. However, the embodiments are not limited thereto. For example, the openings OPN of the pixel defining film PDL may have substantially the same size as that of each of the emission areas EA. In another example, the pixel defining film PDL may have a size larger than that of each of the emission areas EA and may overlap at least a portion of the light blocking layer BM of the color filter layer CFL.

In an embodiment, the openings OPN of the pixel defining film PDL may have different sizes. For example, the openings OPN of the pixel defining film PDL may have sizes corresponding to those of the respective light emitting elements ED or the respectively emission areas EA. For example, the size (or a first aperture ratio of the pixel defining film PDL corresponding to the first emission area EA1) of the first opening OPN1 disposed in the first emission area EA1 of each pixel PX may be larger than the size (or a second aperture ratio of the pixel defining film PDL corresponding to the second emission area EA2) of the second opening OPN2 disposed in the second emission area EA2 of each pixel PX, and may be smaller than the size (or a third aperture ratio of the pixel defining film PDL corresponding to the third emission area EA3) of the third opening OPN3 disposed in the third emission area EA3 of each pixel PX.

In an embodiment, the pixel defining film PDL may include a light absorbing material to reduce or prevent light reflection. For example, the pixel defining film PDL may include a polyimide (PI)-based binder and a pigment in which red, green, and blue colors are mixed. Alternatively, the pixel defining film PDL may include a cardo-based binder resin and a mixture of a lactam black pigment and a blue pigment. Alternatively, the pixel defining film PDL may include carbon black.

The encapsulation layer TFEL may be disposed on the common electrode CE and may cover the light emitting elements ED. In an embodiment, the encapsulation layer TFEL may include at least one inorganic film to inhibit or prevent oxygen or moisture from permeating into the light emitting element layer EML, and may include at least one organic film to protect the light emitting element layer EML from foreign substances such as dust.

In an embodiment, the encapsulation layer TFEL may include a first encapsulation layer TFE1, a second encapsulation layer TFE2, and a third encapsulation layer TFE3 sequentially disposed on the light emitting elements ED. The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 may be an organic encapsulation layer.

Each of the first encapsulation layer TFE1 and the third encapsulation layer TFE3 may include an inorganic insulating material. For example, each of the first encapsulating layer TFE1 and the third encapsulating layer TFE3 may include aluminum oxide, titanium oxide, tantalum oxide, hafnium oxide, zinc oxide, silicon oxide, silicon nitride, or silicon oxynitride and/or another inorganic insulating material.

The second encapsulation layer TFE2 may include an organic insulating material. For example, the second encapsulation layer TFE2 may include a polymer-based organic insulating material such as acrylic resin, epoxy resin, polyimide, or polyethylene, or may include another organic insulating material. The second encapsulation layer TFE2 may be formed by curing a monomer or applying a polymer.

The touch sensing layer TSU may be disposed on the encapsulation layer TFEL. For example, the touch sensing layer TSU may be disposed between the display layer DU and the color filter layer CFL. However, embodiments are not limited thereto, and the location of the touch sensing layer TSU may be changed. In another embodiment, the touch sensing layer TSU and the display layer DU may be integrated, or the display device 10 may not include a separate touch sensing layer TSU. In this case, the color filter layer CFL may be disposed on the display layer DU. For example, the color filter layer CFL may be disposed directly on the display layer DU.

The touch sensing layer TSU may include a first insulating layer SIL1, a second insulating layer SIL2, the touch electrode TL, and a third insulating layer SIL3. In an embodiment, one of the first insulating layer SIL1 or the third insulating layer SIL3 may be omitted.

The touch sensing layer TSU may include conductive patterns including the touch electrodes TL. The conductive patterns may be sensing patterns used for sensing a touch input. For example, the conductive patterns of the touch sensing layer TSU may be utilized to sense a change in electrical characteristics (e.g., a change in capacitance) according to a touch input, and to detect the touch input.

In an embodiment, the touch electrodes TL may be formed as a mesh pattern including openings exposing the emission areas EA of the pixels PX in plan view. For example, each touch electrode TL or each of a plurality of electrode cells constituting the touch electrode TL may be a mesh pattern disposed in the non-emission area and formed of thin lines overlapping the light blocking layer BM. For example, the touch electrodes TL arranged between the emission areas EA of the pixel PX in FIG. 5 may be different parts of the mesh pattern forming one touch electrode TL. The touch sensing layer TSU may include the plurality of touch electrodes TL arranged at positions corresponding to touch nodes of the display area DA, and the size, resolution, and/or arrangement interval of the touch electrodes TL may be the same as or different from the size, resolution, and/or arrangement interval of the pixels PX.

In an embodiment, the conductive patterns of the touch sensing layer TSU may further include the bridge patterns TBR connecting the touch electrodes TL (or electrode cells forming the touch electrodes TL) in a shape and/or structure. Each bridge pattern TBR may overlap a portion (e.g., two electrode cells included in the touch electrode TL and adjacent to each other) of at least one touch electrode TL, and may be electrically connected to the touch electrode TL.

In an embodiment, the conductive patterns of the touch sensing layer TSU may be disposed in the non-emission area NEA around the emission areas EA, and may be covered with the light blocking layer BM. Accordingly, a visibility of the conductive patterns of the touch sensing layer TSU to the outside may be reduced or prevented.

In an embodiment, the touch sensing layer TSU may include a plurality of conductive layers. For example, the touch sensing layer TSU may include a first conductive layer (e.g., a lower conductive layer) including the bridge patterns TBR and a second conductive layer (e.g., an upper conductive layer) including the touch electrodes TL. The second insulating layer SIL2 may be disposed between the first conductive layer and the second conductive layer. In an embodiment, the first conductive layer may be disposed under the second insulating layer SIL2, and the second conductive layer may be disposed above the second insulating layer SIL2, but the present disclosure is not limited thereto. For example, the arrangement order or position of the first conductive layer and the second conductive layer may be changed.

The first insulating layer SIL1 may be disposed on the encapsulation layer TFEL. The first insulating layer SIL1 may have an insulating function and an optical function. In an embodiment, the first insulating layer SIL1 may include at least one inorganic film. The first insulating layer SIL1 may be omitted.

The bridge pattern TBR may be disposed on the first insulating layer SIL1. The position of the bridge pattern TBR may be changed according to embodiments.

The second insulating layer SIL2 may be disposed on the bridge pattern TBR. For example, the second insulating layer SIL2 may cover the bridge pattern TBR and the first insulating layer SIL1, and may be disposed between the touch electrode TL and the bridge pattern TBR. The second insulating layer SIL2 may include a contact hole through which the touch electrode TL (or the bridge pattern TBR) passes at a portion where the touch electrode TL and the bridge pattern TBR are connected.

The second insulating layer SIL2 may have an insulating function and an optical function. In an embodiment, the second insulating layer SIL2 may be an inorganic film containing at least one of a silicon nitride layer, a silicon oxynitride layer, a silicon oxide layer, a titanium oxide layer, or an aluminum oxide layer. In another embodiment, the second insulating layer SIL2 may be an optically transparent organic film.

The touch electrode TL (or a portion of the touch electrodes TL in the display area DA) may be disposed on the second insulating layer SIL2. The touch electrode TL may include a conductive material and may be formed as a single layer or multiple layers. For example, the touch electrode TL may be formed as a single layer containing molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/Al/ITO) of aluminum and ITO, an Ag—Pd—Cu (APC) alloy, or a stacked structure (ITO/APC/ITO) of APC alloy and ITO.

In an embodiment, the touch electrode TL may not overlap the pixel electrodes AE. For example, the touch electrode TL may be disposed in the non-emission area NEA, and may overlap the pixel defining film PDL and the light blocking layer BM.

In an embodiment, the light blocking layer BM may have a width sufficient to completely cover the touch electrode TL. For example, a width of the light blocking layer BM may be equal to or greater than a width of the touch electrode TL. In an embodiment, the touch electrode TL may be disposed such that the center portion thereof is aligned with the center portion of the light blocking layer BM, and the gap from side portions of the touch electrode TL to edges of the light blocking layer BM may be uniform.

The third insulating layer SIL3 may be disposed on the touch electrode TL. For example, the third insulating layer SIL3 may cover the touch electrode TL and the second insulating layer SIL2. The third insulating layer SIL3 may have an insulating function and an optical function. In an embodiment, the third insulating layer SIL3 may include a material exemplified as the material of the second insulating layer SIL2. The third insulating layer SIL3 may be omitted.

The color filter layer CFL may be disposed on the light emitting element layer EML. For example, the color filter layer CFL may be disposed on the touch sensing layer TSU, and may cover the light emitting element layer EML, the encapsulation layer TFEL, and the touch sensing layer TSU.

The color filter layer CFL may include the light blocking layer BM, the color filters CF, and at least one passivation layer. For example, the color filter layer CFL may include the light blocking layer BM, the color filters CF, a passivation layer PSV (or a first passivation layer), and an overcoat layer OC (or a second passivation layer).

Although FIG. 5 illustrates an embodiment in which the light blocking layer BM and the color filters CF are formed separately from each other, embodiments are not limited thereto. For example, a display device 10 according to another embodiment may omit at least a portion of the light blocking layer BM of FIG. 5, and light may be blocked by arranging the first color filter CF1, the second color filter CF2, and the third color filter CF3 to overlap each other in the non-emission area NEA.

The light blocking layer BM may be disposed on the touch sensing layer TSU. The light blocking layer BM may be disposed in the non-emission area NEA. The light blocking layer BM may be an opaque pattern including a light absorbing material.

The light blocking layer BM may include openings exposing the pixel electrodes AE. For example, the light blocking layer BM may include openings exposing the respective emission areas EA of the pixels PX arranged in the display area DA in plan view, and may be disposed in the non-emission area NEA of the display area DA. The light blocking layer BM may be disposed entirely in the non-emission area NEA of the display area DA. For example, the emission areas EA of FIG. 4 may correspond to the openings of the light blocking layer BM, and the light blocking layer BM may be disposed in the non-emission area NEA to surround the emission areas EA.

In an embodiment, the opening of the light blocking layer BM corresponding to each emission area EA may have a size greater than that of each opening OPN of the pixel defining film PDL to expose at least a portion of a light emitting element area where each light emitting layer EL is disposed on the pixel electrode AE. However, the embodiments are not limited thereto. For example, the pixel defining film PDL and the light blocking layer BM may be opened with substantially the same area in the sub-pixel area where each sub-pixel SPX is disposed.

In describing embodiments, the light transmitting areas where the light emitting elements are exposed by the openings of the light blocking layer BM may be defined as the emission areas EA, and the light blocking area where the light blocking layer BM is disposed may be defined as the non-emission area NEA, but the criteria for distinguishing the emission areas EA and the non-emission area NEA may vary. For example, the areas where the pixel electrodes AE are exposed by the openings OPN of the pixel defining film PDL may be defined as the emission areas EA.

The color filters CF may be disposed on the touch sensing layer TSU and the light blocking layer BM. The color filters CF may be disposed in the respective emission areas EA and overlap the respective light emitting elements ED. In an embodiment, the color filters CF may also be disposed around the respective emission areas EA, and at least two color filters CF adjacent between the emission areas EA may overlap each other. For example, the edge portion of each of the color filters CF may be disposed on the light blocking layer BM and/or at least one other color filter CF. Accordingly, the color filters CF may have a concave cross-sectional shape in which the height of the central portion disposed in each emission area EA is lower than the height of the edge portion.

The first color filter CF1 may be disposed in the first emission area EA1 and overlap the first light emitting element ED1. In an embodiment, the edge portion of the first color filter CF1 may be disposed around the first emission area EA1 and overlap a portion of the light blocking layer BM. For example, in plan view, the edge portion of the first color filter CF1 may surround the first emission area EA1, and may be disposed on a portion of the light blocking layer BM.

The second color filter CF2 may be disposed in the second emission area EA2 and overlap the second light emitting element ED2. In an embodiment, the edge portion of the second color filter CF2 may be disposed around the second emission area EA2 and overlap a portion of the light blocking layer BM. For example, in plan view, the edge portion of the second color filter CF2 may surround the second emission area EA2, and may be disposed on a portion of the light blocking layer BM.

The third color filter CF3 may be disposed in the third emission area EA3 and overlap the third light emitting element ED3. In an embodiment, the edge portion of the third color filter CF3 may be disposed around the third emission area EA3 and overlap a portion of the light blocking layer BM. For example, in plan view, the edge portion of the third color filter CF3 may surround the third emission area EA3, and may be disposed on a portion of the light blocking layer BM.

The color filters CF may contain a colorant such as a dye or a pigment that absorbs light of a wavelength band other than a specific wavelength band. For example, the first color filter CF1 may transmit light of the first color emitted from the first light emitting element ED1 of the first emission area EA1, and may absorb and/or block light of other colors (e.g., light of the second color and light of the third color). For example, the first color filter CF1 may be a red color filter that selectively transmits red light emitted from the first light emitting element ED1. The second color filter CF2 may transmit light of the second color emitted from the second light emitting element ED2 of the second emission area EA2, and may absorb and/or block light of other colors (e.g., light of the first color and light of the third color). For example, the second color filter CF2 may be a green color filter that selectively transmits green light emitted from the second light emitting element ED2. The third color filter CF3 may transmit light of the third color emitted from the third light emitting element ED3 of the third emission area EA3, and may absorb and/or block light of other colors (e.g., light of the first color and light of the second color). For example, the third color filter CF3 may be a blue color filter that selectively transmits blue light emitted from the third light emitting element ED3.

By arranging the color filters CF and the light blocking layer BM on the display layer DU, the intensity of reflected light due to external light may be reduced. Accordingly, the deterioration of image quality due to external light may be reduced.

In an embodiment, the color filters CF may have thicknesses that are adjusted or optimized according to the light efficiency of the pixels PX. For example, the color filters CF may have thicknesses that are differentiated or optimized according to the light emission efficiency of light generated from the respective light emitting elements ED, for example, the color filter transmittance of light generated from the respective light emitting elements ED.

In an embodiment, the first color filter CF1 may have a first thickness d1 that is adjusted or optimized according to the light emission efficiency of the first color light emitted from the first light emitting element ED1, the second color filter CF2 may have a second thickness d2 that is adjusted or optimized according to the light emission efficiency of the second color light emitted from the second light emitting element ED2, and the third color filter CF3 may have a third thickness d3 that is adjusted or optimized according to the light emission efficiency of the third color light emitted from the third light emitting element ED3. In describing embodiments, the thicknesses of the color filters CF may be compared with respect to the central portions of the color filters CF arranged in the emission areas EA. For example, the central portions of the first color filter CF1, the second color filter CF2, and the third color filter CF3 may have substantially a first thickness d1, a second thickness d2, and a third thickness d3, respectively, and the first thickness d1, the second thickness d2, and the third thickness d3 may be thicknesses set to optimize the front light emission efficiency of the sub-pixels SPX. In an embodiment, the thickness of the edge portion of each of the color filters CF may be less than the thickness of the central portion of each of the color filters CF.

In an embodiment, the first thickness d1 may be less than the second thickness d2 and the third thickness d3, and the second thickness d2 may be greater than the first thickness d1 and the third thickness d3. For example, the first color filter CF1 may have the smallest thickness, and the second color filter CF2 may have the largest thickness. The third color filter CF3 may have an intermediate thickness. However, embodiments are not limited thereto, and the thicknesses of the color filters CF may vary depending on the light emission efficiency of the respective light emitting elements ED, the optimal ratio of the first color light, the second color light, and the third color light that are emitted from the respective emission areas EA, or other various factors.

The passivation layer PSV and the overcoat layer OC may be sequentially arranged on the light blocking layer BM and the color filters CFL. The passivation layer PSV and the overcoat layer OC may be arranged entirely in the display area DA to flatten the stepped portion caused by the color filters CF and the light blocking layer BM and protect the display panel 100.

The passivation layer PSV and the overcoat layer OC may have a light transmitting property. In an embodiment, the passivation layer PSV and the overcoat layer OC may include a colorless light transmissive organic material such as an acrylic resin.

In the display device 10 according to embodiments, the side luminance and/or viewing angle of the sub-pixels SPX and the pixels PX including the same may vary depending on the width of the light blocking layer BM. For example, if the width of the light blocking layer BM is decreased, the side light emitted in the lateral direction of the pixels PX may be increased, so that the side luminance ratio and/or viewing angle of the pixels PX may be improved. However, if the width of the light blocking layer BM is decreased, the reflectivity (e.g., external light reflectivity) of the display panel 100 may be increased, so that the image quality of the display device 10 may be deteriorated. On the other hand, if the width of the light blocking layer BM is increased, the reflectivity (e.g., external light reflectivity) of the display panel 100 may be decreased, but the blocking rate of the side light by the light blocking layer BM is increased, so that the side luminance ratio and/or viewing angle of the pixels PX may be deteriorated.

Further, in the display device 10 according to embodiments, color filter transmission lengths according to paths where front light emitted in the front direction (e.g., the third direction DR3) and side light emitted in the lateral direction from the light emitting element ED disposed in each emission area EA transmit through each color filter CF may be different. For example, a color filter transmission length L1 in which front light Lf emitted from the second light emitting element ED2 in the third direction DR3 transmits through the second color filter CF2 may correspond to the second thickness d2 of the second color filter CF2. On the other hand, color filter transmission lengths L2 and L3 in which first side light Ls1 and second side light Ls2 emitted from the second light emitting element ED2 of the second sub-pixel SPX2 transmit through the second color filter CF2 may be greater than the second thickness d2 of the second color filter CF2. The color filter transmission length of the side light emitted from each light emitting element ED may vary depending on the shape of the color filter CF disposed on the light emitting element ED, the thickness of the color filter CF, and/or the path through which the side light passes.

In each pixel PX, the light emission ratio of the side light emitted from each light emitting element ED may be different depending on the size (e.g., light emitting area) of the emission areas EA or the aperture ratio of the pixel defining film PDL. For example, the size of the second emission area EA2 may be smaller than the size of each of the first emission area EA1 and the third emission area EA3, so that the light emission ratio of the side light of the second color may be lower than the light emission ratio of the side light of the first color and the light emission ratio of the side light of the third color. Accordingly, color shift may occur when an image displayed in the display area DA is viewed from the side. For example, since the side light emission ratio of the second color light may be lower than the side light emission ratio of the first color light and the side light emission ratio of the third color light, the viewing angle color shift may occur, and a side color of the image may be changed. The side color of a sub-pixel SPX may be an angular emission of the sub-pixel. A distance the angular emission travels within a color filter CF may be greater than a distance traveled by front light Lf through the color filter CF, which may be substantially perpendicular to a surface of the light emitting element ED.

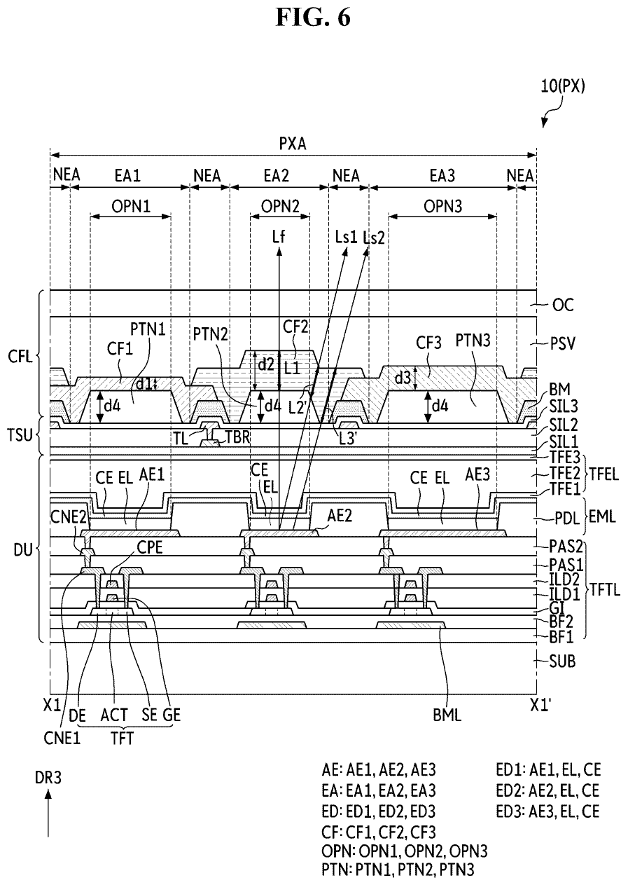

FIG. 6 is a cross-sectional view showing a display device according to an embodiment. For example, FIG. 6, which shows a portion of the display device 10 corresponding to the cross section of the pixel PX along line X1-X1′ of FIG. 4, shows an embodiment different from the embodiment of FIG. 5 in relation to the color filter layer CFL.

In describing the following embodiments, components substantially identical or similar to those of at least an embodiment described above are designated with the same reference numerals, and redundant descriptions will be omitted. Further, each embodiment may be applied alone or in combination with at least one other embodiment, and all possible combinations of embodiments may fall within the scope of the present disclosure.

Referring to FIGS. 1 to 6, the display device 10 according to an embodiment may further include patterns PTN disposed under at least some of the color filters CF in the respective emission areas EA. For example, the patterns PTN may be arranged between the respective light emitting elements ED and the respective color filters CF. In an embodiment, the patterns PTN may be arranged in the color filter layer CFL, but are not limited thereto. In an embodiment, the patterns PTN may be light transmitting patterns.

In an embodiment, the patterns PTN may be formed as individual patterns arranged in the respective emission areas EA. The patterns PTN may be spaced apart from the light blocking layer BM. For example, the patterns PTN may expose a portion of the top surface of the touch sensing layer TSU disposed between the patterns PTN and the light blocking layer BM. The patterns PTN may be surrounded by the light blocking layer BM in plan view.

The patterns PTN may have a light transmitting property. For example, the patterns PTN may be substantially transparent, and thus may have a light transmitting property. For example, the patterns PTN may be a transparent pattern having an optical transmission greater than about 90% or greater than about 95%. Accordingly, light emitted from the light emitting elements ED may transmit through the patterns PTN. The patterns PTN may also be referred to as “light transmitting patterns.” The patterns PTN may be formed of an organic material or an inorganic material, and the material of the patterns PTN is not particularly limited.

The patterns PTN may be used as a profile control layer (or light control layer) for changing or controlling the shape of the color filters CF. For example, the patterns PTN may form a stepped portion under the color filters CF, so that the color filters CF may have a shape (e.g., a cross-sectional shape corresponding to the patterns PTN) corresponding to the patterns PTN. For example, a thickness or height of a patterns PTN may be different for each of the color filters CF, and the shape and/or height of the color filters CF may be adjusted according to the thickness or height of the patterns PTN. For example, the color filters CF may be conformal layers at least in part.

In an embodiment, a first pattern PTN1, a second pattern PTN2, and a third pattern PTN3 may be arranged under the first color filter CF1, the second color filter CF2, and the third color filter CF3, respectively. Accordingly, the first color filter CF1, the second color filter CF2, and the third color filter CF3 may have shapes corresponding to those of the first pattern PTN1, the second pattern PTN2, and the third pattern PTN3, respectively.

In an embodiment, the patterns PTN may be arranged on the respective light emitting elements ED. For example, the first pattern PTN1 may be disposed on the first light emitting element ED1, and may completely or partially cover the first opening OPN1 of the pixel defining film PDL. The second pattern PTN2 may be disposed on the second light emitting element ED2, and may completely or partially cover the second opening OPN2 of the pixel defining film PDL. The third pattern PTN3 may be disposed on the third light emitting element ED3, and may completely or partially cover the third opening OPN3 of the pixel defining film PDL.

Herein, the color filters CF may be described in terms of convex and concave shapes. It should be understood that these terms may be used to describe the properties of a shape based on its geometry and how its boundary behaves, and these terms may be applied to both curved shapes and polygonal shapes. For example, a shape may be convex if any line segment drawn between two points within the shape lies entirely inside the shape, and shape may be concave if there exists at least one line segment drawn between two points within the shape that passes outside of the shape.

The first color filter CF1 may protrude in a height direction on the first pattern PTN1, and thus may have a convex cross-sectional shape. For example, the first color filter CF1 may include a central portion having a shape and/or size corresponding to that of the first pattern PTN1 and protruding higher than the periphery, and an edge portion having a height lower than that of the central portion. In plan view, the central portion of the first color filter CF1 may be disposed in the first emission area EA1 and overlap the first pattern PTN1, and the edge portion of the first color filter CF1 may surround the central portion of the first color filter CF1 and the first pattern PTN1. The edge portion of the first color filter CF1 may overlap the light blocking layer BM in the non-emission area NEA.

The second color filter CF2 may protrude in the height direction on the second pattern PTN2, and thus may have a convex cross-sectional shape. For example, the second color filter CF2 may include a central portion having a shape and/or size corresponding to that of the second pattern PTN2 and protruding higher than the periphery, and an edge portion having a height lower than that of the central portion. In plan view, the central portion of the second color filter CF2 may be disposed in the second emission area EA2 and overlap the second pattern PTN2, and the edge portion of the second color filter CF2 may surround the central portion of the second color filter CF2 and the second pattern PTN2. The edge portion of the second color filter CF2 may overlap the light blocking layer BM in the non-emission area NEA.

The third color filter CF3 may protrude in the height direction on the third pattern PTN3, and thus may have a convex cross-sectional shape. For example, the third color filter CF3 may include a central portion having a shape and/or size corresponding to that of the third pattern PTN3 and protruding higher than the periphery, and an edge portion having a height lower than that of the central portion. In plan view, the central portion of the third color filter CF3 may be disposed in the third emission area EA3 and overlap the third pattern PTN3, and the edge portion of the third color filter CF3 may surround the central portion of the third color filter CF3 and the third pattern PTN3. The edge portion of the third color filter CF3 may overlap the light blocking layer BM in the non-emission area NEA.

In an embodiment, at least a portion of the color filters CF may have thicknesses according to the light emission efficiency of the light emitting element ED, in addition to the convex cross-sectional shape. For example, a portion of the first color filter CF1 on the first pattern PTN1 may have the first thickness d1, a portion the second color filter CF2 on the second pattern PTN2 may have the second thickness d2, and a portion of the third color filter CF3 on the third pattern PTN3 may have the third thickness d3.

In an embodiment, the patterns PTN may be formed with a substantially uniform thickness. For example, the first pattern PTN1, the second pattern PTN2, and the third pattern PTN3 may have substantially the same fourth thickness d4.

According to some embodiments, the side luminance ratio and the viewing angle of the pixel PX may be improved. For example, since the central portions of the color filters CF arranged on the respective light emitting elements ED protrude by the patterns PTN, the side light emitted from the first emission area EA1, the second emission area EA2, and the third emission area EA3 of the pixel PX may be increased. Accordingly, compared to the pixel PX of FIG. 5 that does not include the patterns PTN, the color filter transmission length of at least a portion of the side light may be reduced or minimized in the pixel PX of FIG. 6. Accordingly, the difference between the color filter transmission length of the front light and the color filter transmission length of the side light may be reduced, and the side luminance ratio may be improved (e.g., increased). For example, since the second color filter CF2 has a convex shape, color filter transmission lengths L2′ and L3′ of the first side light Ls1 and the second side light Ls2 emitted from the second emission area EA2 may be reduced or minimized. Similarly, since the first color filter CF1 and the third color filter CF3 have a convex shape, the side light emitted from the first emission area EA1 and the third emission area EA3 may be increased. Since the amount of the side light emitted from the pixel PX is increased, the difference between the front luminance and the side luminance of the pixel PX may be reduced or minimized, and the side luminance ratio and the viewing angle of the pixel PX may be increased.

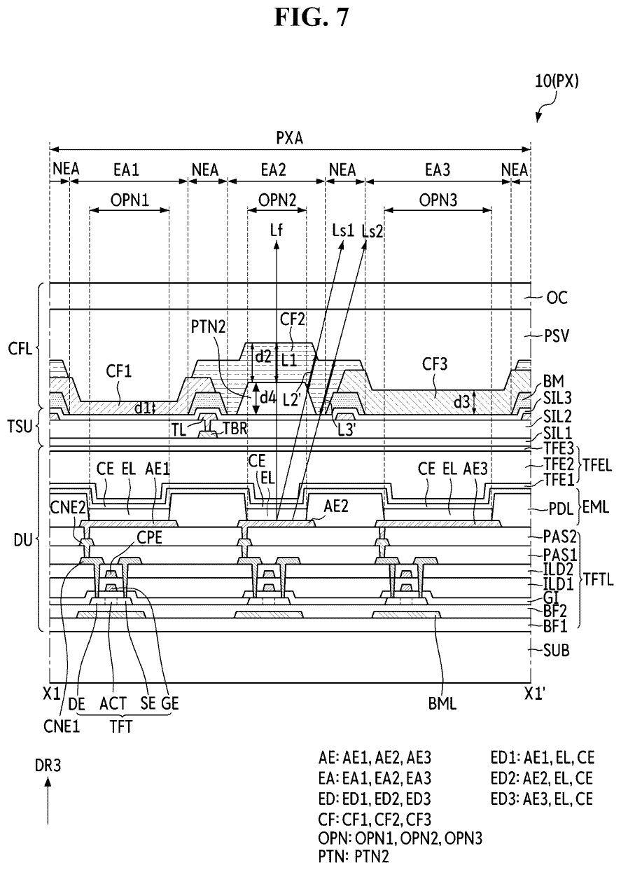

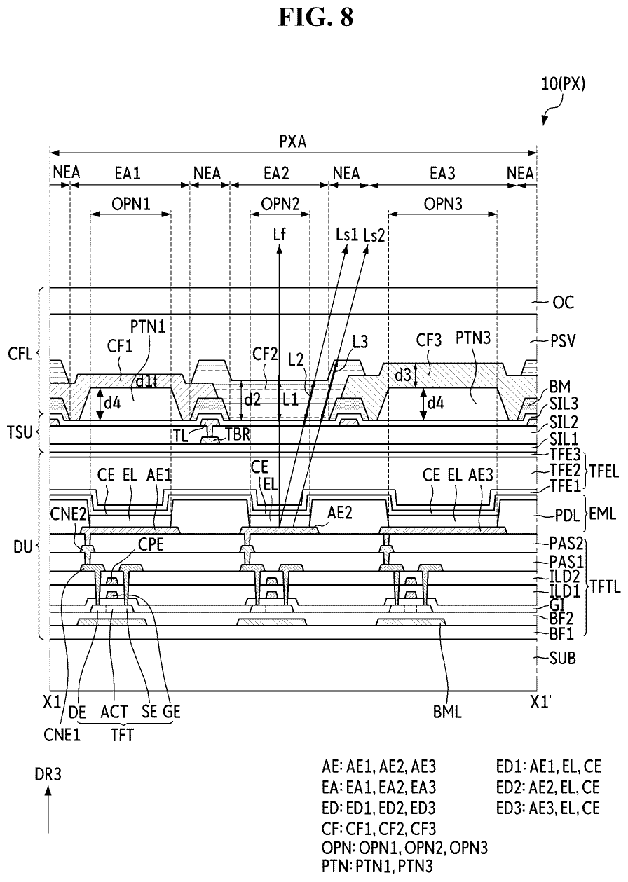

FIG. 7 is a cross-sectional view showing a display device according to an embodiment. FIG. 8 is a cross-sectional view showing a display device according to an embodiment. For example, FIG. 7 and FIG. 8, which show a portion of the display device 10 corresponding to the cross section of the pixel PX along line X1-X1′ of FIG. 4, show embodiments that are different from the embodiment of FIG. 6 in relation to the patterns PTN.

Referring to FIG. 7 and FIG. 8 in addition to FIGS. 1 to 6, the patterns PTN may be disposed in some emission areas EA among the emission areas EA of each pixel PX. For example, the patterns PTN may be arranged in all the emission areas EA of the pixel PX as shown in FIG. 6, or may be selectively and/or differentially disposed in some emission areas EA among the emission areas EA of the pixel PX as shown in FIG. 7 and FIG. 8. Depending on the selective and/or differential arrangement of the patterns PTN, at least two color filters CF among the color filters CF of the sub-pixels SPX may have different cross-sectional shapes.

In an embodiment, as illustrated in FIG. 7, the first pattern PTN1 and the third pattern PTN3 of FIG. 6 may not be arranged in the first emission area EA1 and the third emission area EA3, and the second pattern PTN2 may be disposed in the second emission area EA2. For example, the pattern PTN may have one or more openings. In FIG. 7, the pattern PTN may have a first opening in the first emission area EA1 and a second opening in the third emission area EA3. In the first opening in the first emission area EA1, the first color filter CF1 may be disposed directly on the touch sensing layer TSU, and in the second opening in the third emission area EA3, the third color filter CF3 may be disposed directly on the touch sensing layer TSU. Accordingly, the first color filter CF1 and the third color filter CF3 may have a concave cross-sectional shape, and the second color filter CF2 may have a convex cross-sectional shape. Since the second color filter CF2 has a convex cross-sectional shape, the side luminance ratio of the light of the second color emitted from the second emission area EA2 of the second sub-pixel SPX2 may be increased. Accordingly, the side luminance ratio difference between the sub-pixels SPX may be reduced, and the color of the pixel PX may be improved. For example, by disposing the second pattern PTN2 in the second emission area EA2 of the second sub-pixel SPX2 having the smallest emission area EA and the lowest side luminance ratio, the side luminance ratio of the second sub-pixel SPX2 may be increased, thereby reducing or minimizing the side luminance ratio difference between the first sub-pixel SPX1, the second sub-pixel SPX2, and the third sub-pixel SPX3. Accordingly, the color change (e.g., phenomenon in which the color of the image becomes reddish or blueish) of the image according to the viewing angle may be reduced or minimized, and the side color of the display device 10 may be improved.

In an embodiment, as illustrated in FIG. 7, a different between the color filter transmission lengths L1, L2′ and L3′ of the front light Lf, the first side light Ls1, and the second side light Ls2 emitted from the second emission area EA2 may be reduced or minimized. For example, the color transmission length L1 of the front light Lf may be greater than the color filter transmission length L2′ of the first side light Ls1 and less than the color filter transmission length L3′ of the second side light Ls2. For example, a color purity of the second emission area EA2 may be improved.

In an embodiment, a color filter may be omitted from at least one emission area. For example, the first color filter CF1 may be omitted from the first emission area EA1. For example, the sub-pixel corresponding to the first emission area EA1 may be emit blue light.

In another embodiment, as illustrated in FIG. 8, the first pattern PTN1 and the third pattern PTN3 may be arranged in the first emission area EA1 and the third emission area EA3, respectively, and the second pattern PTN2 of FIG. 6 may not be disposed in the second emission area EA2. Accordingly, the first color filter CF1 and the third color filter CF3 may have a convex cross-sectional shape, and the second color filter CF2 may have a concave cross-sectional shape. Since the first color filter CF1 and the third color filter CF3 have a convex cross-sectional shape, the side luminance ratios of the first color light emitted from the first sub-pixel SPX1 and the third color light emitted from the third sub-pixel SPX3 may be increased. Accordingly, the side luminance ratio difference between of the sub-pixels SPX in a specific viewing angle range may be reduced, and the color of the pixel PX may be improved.

Mismatched side color distributions of sub-pixels SPX may result in angular color shift. For example, in a case that the angular distributions of red and blue sub-pixels decline faster than that of a green sub-pixel, a white point of emitted light may appear greenish at large viewing angles. Accordingly, the side color of the display device 10 may have a color shift (e.g., a green color shift) in a specific viewing angle range (e.g., viewing angle of about) 60° depending on the arrangement pattern of the emission areas EA or the like. In some embodiments, the side luminance ratios of the first sub-pixel SPX1 and the third sub-pixel SPX3 may be increased by changing the shapes of the first color filter CF1 and the third color filter CF3 by the first pattern PTN1 and the third pattern PTN3. Accordingly, the phenomenon in which the side color of the display device 10 has a color shift may be prevented or mitigated, and the side luminance ratio and the side color of the display device 10 may be improved.

In addition, embodiments reflecting possible combinations related to the selective and/or differential arrangement of the patterns PTN may fall within the scope of the present disclosure. For example, the pattern PTN having a light transmitting property may be disposed under the color filter CF in at least one emission area EA among the emission areas EA of the pixel PX, and the color filter CF on the pattern PTN may have a convex cross-sectional shape corresponding to that of the pattern PTN. In an embodiment, the side luminance ratio and/or side color of the pixel PX and the display device 10 including the same may be adjusted or improved according to the patterns PTN selectively and/or differentially arranged in the emission areas EA of the pixel PX.

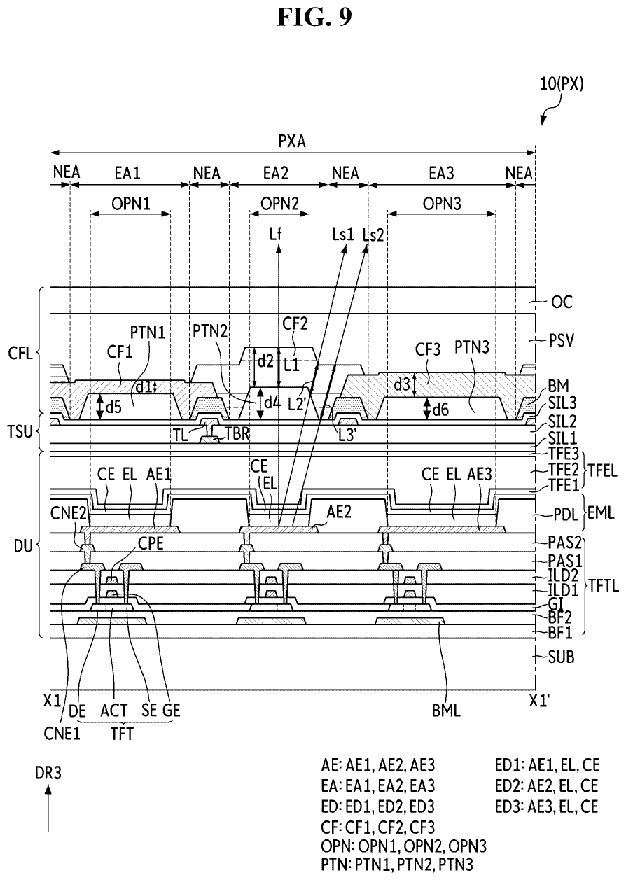

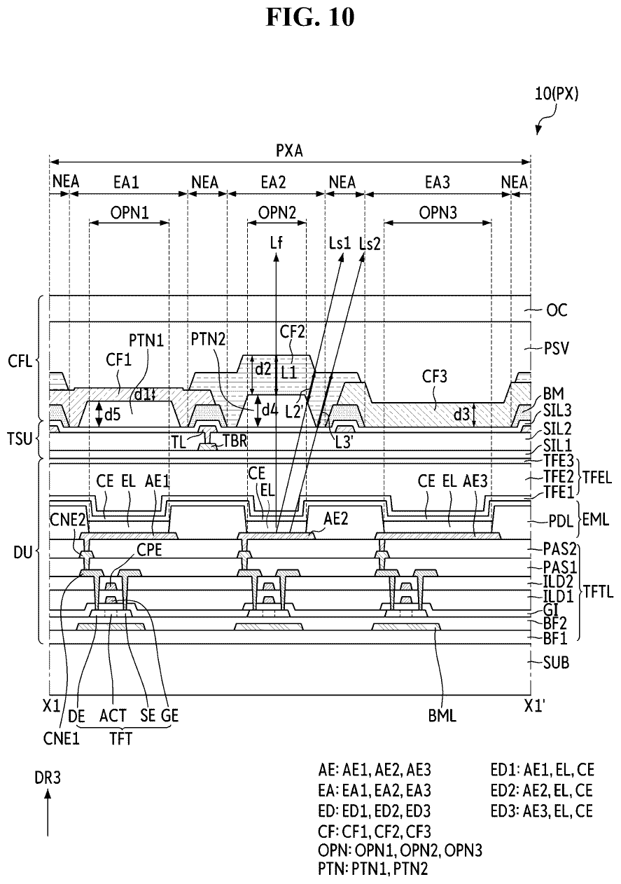

FIG. 9 is a cross-sectional view illustrating a display device according to an embodiment. FIG. 10 is a cross-sectional view showing a display device according to an embodiment. For example, FIG. 9 and FIG. 10, which show a portion of the display device 10 corresponding to the cross section of the pixel PX along line X1-X1′ of FIG. 4, show embodiments that are different from the embodiments of FIGS. 6 to 8 in relation to the patterns PTN.

Referring to FIG. 9 and FIG. 10, the patterns PTN may be differentially and/or selectively arranged in the emission areas EA of each pixel PX. For example, by differentiating at least one of the arrangement, size, or shape of the pattern PTN, the shapes of the color filters CF arranged in the respective emission areas EA or the side luminance ratios determined therefrom may be changed or differentiated. For example, to reduce or minimize the side luminance ratio difference due to the size difference of the emission areas EA, the patterns PTN may be selectively arranged according to the sizes of the emission areas EA, or the sizes (e.g., areas and/or thicknesses) of the patterns PTN may be differentiated. By differentiating the arrangement and/or the sizes of the patterns PTN, at least two color filters CF among the color filters CF of the sub-pixels SPX may have different cross-sectional shapes.

In an embodiment, as illustrated in FIG. 9, the respective patterns PTN may be arranged in all the emission areas EA of the pixel PX, and the thicknesses of the patterns PTN arranged in at least two emission areas EA may be differentiated. For example, the first pattern PTN1, the second pattern PTN2, and the third pattern PTN3 may have a fifth thickness d5, a fourth thickness d4, and a sixth thickness d6, respectively. In an embodiment, the pattern PTN having the largest thickness may be disposed in the smallest emission area EA having a relatively low side luminance ratio to increase the side luminance ratio of the emission area EA to a greater extent. For example, the second pattern PTN2 disposed in the second emission area EA2 may have the fourth thickness d4 greater than the thicknesses of the first pattern PTN1 and the third pattern PTN3, so that the side luminance ratio of the second emission area EA2 may be increased to the greatest extent. The first pattern PTN1 disposed in the first emission area EA1 of an intermediate size may have the fifth thickness d5 corresponding to an intermediate thickness, and the third pattern PTN3 disposed in the third emission area EA3 of the largest size may have the sixth thickness d6 corresponding to the smallest thickness. For example, the fifth thickness d5 may be greater than the sixth thickness d6 and may be less than the fourth thickness d4. Accordingly, the side luminance ratio difference according to the sizes of the emission areas EA may be reduced, and the side color of the pixel PX may be corrected or improved.

In another embodiment, as illustrated in FIG. 10, each pattern PTN may be disposed in some of the emission areas EA of the pixel PX, and the pattern PTN may not be disposed in the other emission areas EA. For example, the first pattern PTN1 and the second pattern PTN2 may be arranged in the first emission area EA1 and the second emission area EA2, respectively, and the third pattern PTN3 according to the embodiments of FIG. 6, FIG. 8, and FIG. 9 may not be disposed in the third emission area EA3. Optionally, the thicknesses of the patterns PTN may be differentiated also in the first emission area EA1 and the second emission area EA2. For example, the first pattern PTN1 having the fifth thickness d5 may be disposed in the first emission area EA1, and the second pattern PTN2 having the fourth thickness d4 may be disposed in the second emission area EA2. Accordingly, the side luminance ratio difference according to the sizes of the emission areas EA may be reduced, and the side color of the pixel PX may be corrected or improved.

In addition to the embodiments described with reference to FIGS. 8 to 10, embodiments reflecting possible combinations in relation to the selective and/or differential arrangement of the patterns PTN, and/or size adjustment of the patterns PTN may all fall within the scope of the present disclosure. In an embodiment, in order to adjust or improve the side luminance ratio and/or side color of the pixel PX and the display device 10 including the same in a desired manner, the patterns PTN may be selectively and/or differentially arranged in the emission areas EA of the pixel PX. Further, the thicknesses of the patterns PTN may be uniformly formed or differentiated.

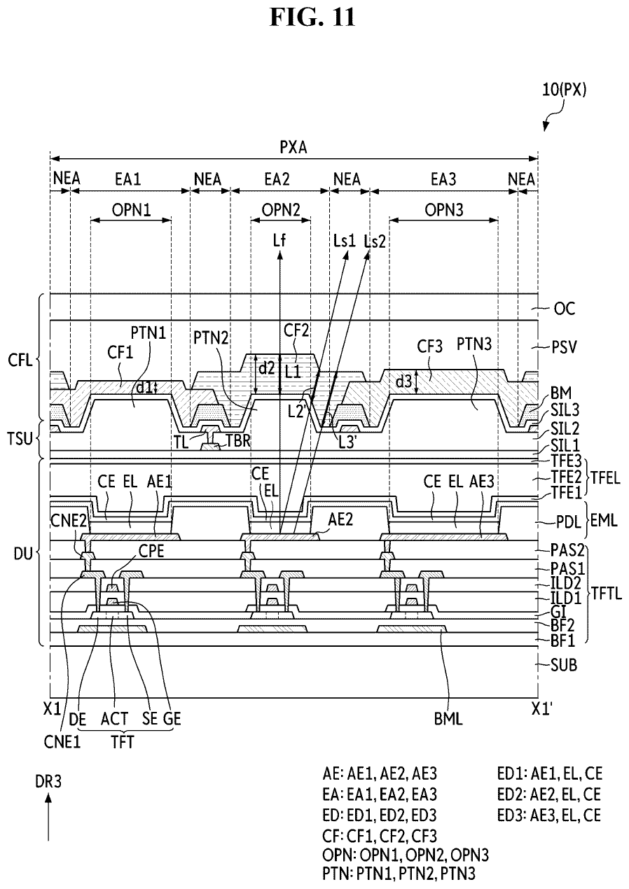

FIG. 11 is a cross-sectional view showing a display device according to an embodiment. For example, FIG. 11, which shows a portion of the display device 10 corresponding to the cross section of the pixel PX along line X1-X1′ of FIG. 4, shows embodiments different from the embodiments of FIGS. 6 to 10 in relation to the patterns PTN.

Referring to FIGS. 1 to 11, the patterns PTN for changing the shape of the color filters CF and the side luminance ratio determined therefrom may be formed integrally with an insulating layer disposed on the touch sensing layer TSU. For example, the touch sensing layer TSU of the display device 10 according to an embodiment may include a second insulating layer SIL2 protruding in the height direction (e.g., the third direction DR3) in the respective emission areas EA. The protruding portions of the second insulating layer SIL2 may form the respective patterns PTN. For example, the second insulating layer SIL2 may partially protrude under the first color filter CF1 to form the first pattern PTN1, partially protrude under the second color filter CF2 to form the second pattern PTN2, and partially protrude under the third color filter CF3 to form the third pattern PTN3.

In an embodiment, the second insulating layer SIL2 may be an optically transparent organic film, but is not limited thereto. In an embodiment, the second insulating layer SIL2 having a different thickness for each portion may be formed by a single mask process using a halftone mask, or the second insulating layer SIL2 having a different thickness for each portion may be formed by forming the second insulating layer SIL2 twice in at least one emission area EA by two mask processes.

The color filters CF may have a shape corresponding to the shape of the second insulating layer SIL2. For example, the first color filter CF1, the second color filter CF2, and the third color filter CF3 may have convex cross-sectional shapes corresponding to those of the first pattern PTN1, the second pattern PTN2, and the third pattern PTN3 of the second insulating layer SIL2, respectively.

Although FIG. 11 discloses an embodiment in which the second insulating layer SIL2 includes the patterns PTN of the same thickness, embodiments are not limited thereto. For example, at least two patterns PTN among the first pattern PTN1, the second pattern PTN2, and the third pattern PTN3 of the second insulating layer SIL2 may have different thicknesses.

Further, although FIG. 11 discloses an embodiment in which the second insulating layer SIL2 protrudes in all the emission areas EA of the pixel PX to form the respective patterns PTN, embodiments are not limited thereto. For example, the second insulating layer SIL2 may not include at least one of the first pattern PTN1, the second pattern PTN2, or the third pattern PTN3, and may be formed substantially flat in at least one emission area EA among the first emission area EA1, the second emission area EA2, and the third emission area EA3 and the non-emission area NEA surrounding the emission area EA. Accordingly, at least one color filter CF among the first color filter CF1, the second color filter CF2, or the third color filter CF3 may have a concave cross-sectional shape, and the other color filters CF may have a convex cross-sectional shape corresponding to that of each pattern PTN.

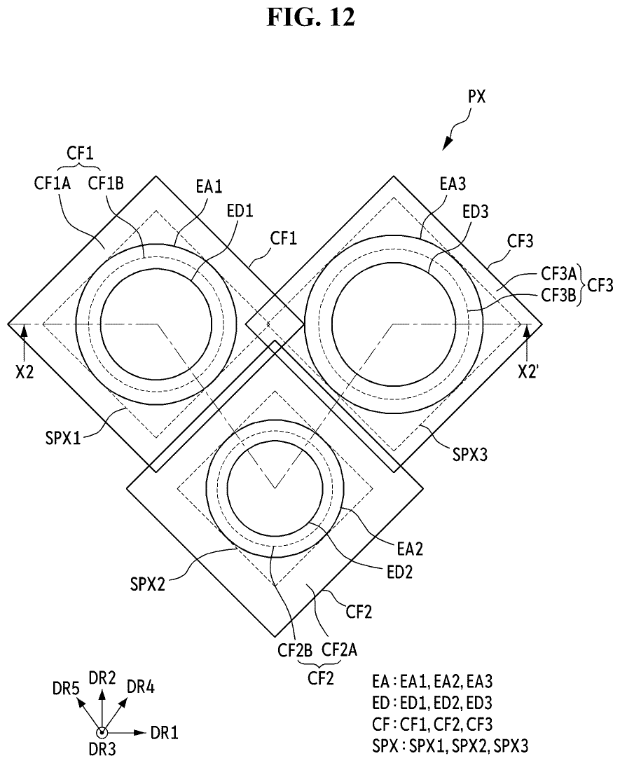

FIG. 12 is a plan view illustrating a pixel of a display device according to an embodiment. For example, FIG. 12, which shows substantial shapes and positions of the emission areas EA of the pixel PX according to an embodiment, and the light emitting elements ED and the color filters CF arranged in the emission areas EA, shows an embodiment different from the embodiment of FIG. 4 in relation to the color filters CF.

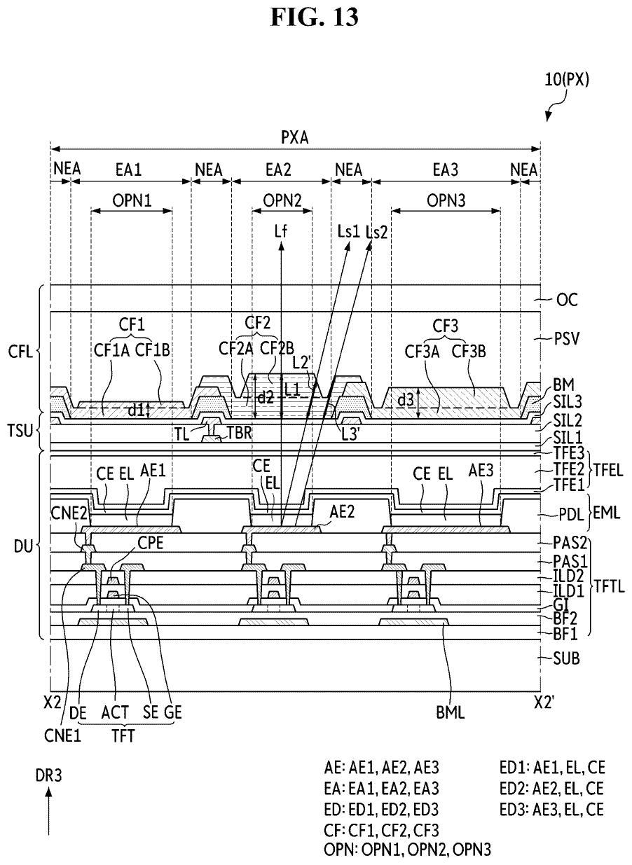

FIG. 13 is a cross-sectional view showing a display device according to an embodiment. For example, FIG. 13 shows a portion of the display device 10 corresponding to a cross section of the pixel PX along line X2-X2′ of FIG. 12.

Referring to FIG. 12 and FIG. 13, the display device 10 may not include the patterns PTN according to the embodiments described above, and at least one color filter CF may have a thickness greater at the central portion disposed on each light emitting element ED than at the other portions, and may have a substantially convex cross-sectional shape. For example, the first color filter CF1, the second color filter CF2, and the third color filter CF3 may have thicknesses greater at the central portions disposed on the first light emitting element ED1, the second light emitting element ED2, and the third light emitting element ED3, respectively, than at the other portions, and may have a substantially convex cross-sectional shape.

In an embodiment, at least a portion of the color filters CF may have thicknesses according to the light emission efficiency of the light emitting elements ED, in addition to the cross-sectional shape or the like. For example, a portion of the first color filter CF1 on the first light emitting element ED1 may have the first thickness d1, the second color filter CF2 on the second light emitting element ED2 may have the second thickness d2, and the third color filter CF3 on the third light emitting element ED3 may have the third thickness d3.

In an embodiment, the color filters CF may include lower layer portions CF1A, CF2A, and CF3A, and upper layer portions CF1B, CF2B, and CF3B disposed on a portion of the lower layer portions CF1A, CF2A, and CF3A. In an embodiment, a thickness of a central portion of each of the color filters CF may be equal to a combined height of the lower layer portion and the upper layer portion, where the central portion overlaps the respective light emitting elements ED. The thickness of each color filter CF including the thicknesses of the lower layer portions CF1A, CF2A, and CF3A and the thicknesses of the upper layer portions CF1B, CF2B, and CF3B may correspond to a thickness selected according to the light emission efficiency of the light emitting elements ED.

For example, the first thickness d1 of a portion of the first color filter CF1 overlapping the first light emitting element ED1 may include the lower layer portion CF1A having a thickness greater than a thickness of the upper layer portion CF1B. The lower layer portion CF1A of the first color filter CF1, which is disposed generally in the first color filter area where the first color filter CF1 is disposed, may be disposed in the first emission area EA1 and the non-emission area NEA around the first emission area EA1. The upper layer portion CF1B of the first color filter CF1 may be disposed on the first light emitting element ED1, and may completely or partially cover the first opening OPN1 of the pixel defining film PDL. For example, the upper layer portion CF1B of the first color filter CF1 may be disposed in the first emission area EA1 to cover the first light emitting element ED1. In the first emission area EA1, the total thickness of the first color filter CF1 corresponding to the sum of the thickness of the lower layer portion CF1A and the thickness of the upper layer portion CF1B of the first color filter CF1 may be the first thickness d1. Accordingly, the side luminance ratio may be improved while maintaining the front light emission ratio of the first sub-pixel SPX1 including the first emission area EA1.

The second thickness d2 of a portion of the second color filter CF2 overlapping the second light emitting element ED2 may include the lower layer portion CF2A having a thickness about equal to a thickness of the upper layer portion CF2B. The lower layer portion CF2A of the second color filter CF2, which is disposed generally in the second color filter area where the second color filter CF2 is disposed, may be disposed in the second emission area EA2 and the non-emission area NEA around the second emission area EA2. The upper layer portion CF2B of the second color filter CF2 may be disposed on the second light emitting element ED2, and may completely or partially cover the second opening OPN2 of the pixel defining film PDL. For example, the upper layer portion CF2B of the second color filter CF2 may be disposed in the second emission area EA2 to cover the second light emitting element ED2. In the second emission area EA2, the total thickness of the second color filter CF2 corresponding to the sum of the thickness of the lower layer portion CF2A and the thickness of the upper layer portion CF2B of the second color filter CF2 may be the second thickness d2. Accordingly, the side luminance ratio may be improved while maintaining the front light emission ratio of the second sub-pixel SPX2 including the second emission area EA2.

The third thickness d3 of a portion of the third color filter CF3 overlapping the third light emitting element ED3 may include the lower layer portion CF3A having a thickness less than a thickness of the upper layer portion CF3B. The lower layer portion CF3A of the third color filter CF3, which is disposed generally in the third color filter area where the third color filter CF3 is disposed, may be disposed in the third emission area EA3 and the non-emission area NEA around the third emission area EA3. The upper layer portion CF3B of the third color filter CF3 may be disposed on the third light emitting element ED3, and may completely or partially cover the third opening OPN3 of the pixel defining film PDL. For example, the upper layer portion CF3B of the third color filter CF3 may be disposed in the third emission area EA3 to cover the third light emitting element ED3. In the third emission area EA3, the total thickness of the third color filter CF3 corresponding to the sum of the thickness of the lower layer portion CF3A and the thickness of the upper layer portion CF3B of the third color filter CF3 may be the third thickness d3. Accordingly, the side luminance ratio may be improved while maintaining the front light emission ratio of the third sub-pixel SPX3 including the third emission area EA3.

In an embodiment, the upper layer portions CF1B, CF2B, and CF3B of the respective color filters CF may have island shapes in plan view and may be arranged in each emission area EA. For example, in plan view, the upper layer portion CF1B, CF2B, and CF3B of the respective color filters CF may be spaced apart from the light blocking layer BM, and may be surrounded by the light blocking layer BM. In cross-sectional view, the upper layer portions CF1B, CF2B, and CF3B of the respective color filters CF may have a convex shape protruding in the height direction (e.g., the third direction DR3).

In an embodiment, the lower layer portions CF1A, CF2A, and CF3A and the upper layer portions CF1B, CF2B, and CF3B of the respective color filters CF may be formed sequentially and/or continuously. For example, after the lower layer portions CF1A, CF2A, and CF3A of the respective color filters CF are formed, the upper layer portions CF1B, CF2B, and CF3B of the respective color filters CF may be formed on a portion of the lower layer portions CF1A, CF2A, and CF3A. In another embodiment, the lower layer portions CF1A, CF2A, and CF3A and the upper layer portions CF1B, CF2B, and CF3B of the respective color filters CF may be formed substantially simultaneously. For example, each color filter CF having a different thickness for each portion and having a substantially convex cross-sectional shape in each emission area EA may be formed by a single mask process using a halftone mask.

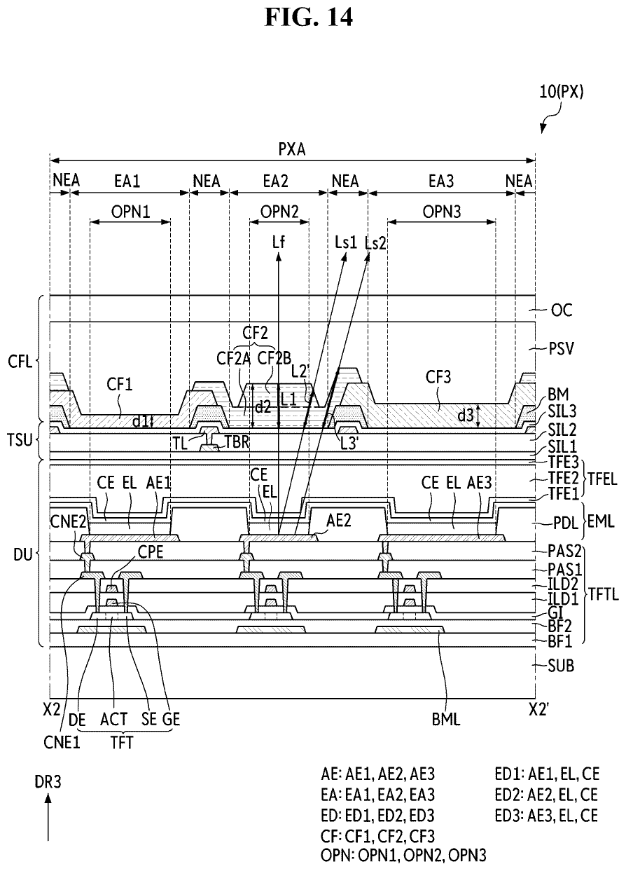

FIG. 14 is a cross-sectional view illustrating a display device according to an embodiment. For example, FIG. 14, which shows the cross section of the pixel PX at a position corresponding to line X2-X2′ of FIG. 12.

Referring to FIG. 14, some color filters CF among the color filters CF may include the upper layer portion (e.g., the upper layer portion CF2B of the second color filter CF2) protruding in the height direction in the emission area EA, and the other color filters CF may have a substantially concave shape. For example, the second color filter CF2 may include the lower layer portion CF2A and the upper layer portion CF2B as in the embodiment of FIG. 12 and FIG. 13 and have a substantially convex cross-sectional shape, and the first color filter CF1 and the third color filter CF3 may have a concave cross-sectional shape as in the embodiments of FIG. 5 and FIG. 7. Accordingly, the side color of the pixel PX and the display device 10 including the same may be adjusted and/or improved.

Referring to FIG. 13 and FIG. 14, the second color filter CF2 may have a convex cross-sectional shape including a central portion disposed as an island its emission area and an edge portion surrounding the central portion. For example, the central portion may be formed by the upper layer portion CF2B. The central portion formed by the upper layer portions CF2B may include a sidewall facing outward. The sidewall of the central portion formed by the upper layer portion CF2B may face a sidewall of the edge portion of the second color filter CF2 disposed in the non-emission area NEA. For example, the upper layer portion CF2B may protrude in a height direction from a gap disposed between the upper layer portion CF2B and the edge portion of the second color filter CF2. In some embodiments, a height of the edge portion may be higher than a height of the second color filter CF2.

As described herein, according to embodiments, at least one color filter CF among the color filters CF of the sub-pixels SPX may be formed to have a convex cross-sectional shape. For example, by disposing the pattern PTN under at least one color filter CF, or by forming an upper layer portion (e.g., one of the upper layer portions CF1B, CF2B, and CF3B) in the at least one color filter CF, the central portion of the at least one color filter CF may protrude in the height direction. Accordingly, the side luminance ratio and the viewing angle of the pixel PX and the display device 10 including the same may be improved.

In some embodiments, the cross-sectional shapes of at least two color filters CF among the color filters CF of the sub-pixels SPX may be differentiated. For example, a first color filter of the color filters CF may be formed to have a convex cross-sectional shape, and a second color filter of the color filters CF may be formed to have a concave cross-sectional shape. Accordingly, the side color of the pixel PX and the display device 10 including the same may be appropriately adjusted and/or improved.

In concluding the detailed description, those skilled in the art will appreciate that many variations and modifications can be made to embodiments without substantially departing from the aspects of the present disclosure. Therefore, embodiments of the invention may be used in a generic and descriptive sense only and not for purposes of limitation.

What is claimed is:

1. A display device comprising:
light emitting elements arranged in emission areas of sub-pixels; and
color filters disposed on the light emitting elements, and overlapping the emission areas and a non-emission area around the emission areas,
wherein a first color filter of the color filters has a convex cross-sectional shape including a central portion disposed in its emission area and an edge portion, the central portion protruding higher than a height of the edge portion, and
at least two of the color filters have different cross-sectional shapes.

2. The display device of claim 1, wherein a second color filter among the color filters has a concave cross-sectional shape including a central portion disposed in its emission area and an edge portion, the central portion having a height lower than a height of the edge portion.

3. The display device of claim 1, further comprising a light transmitting pattern disposed on a light emitting element layer comprising the light emitting elements and disposed under the first color filter.

4. The display device of claim 3, wherein the first color filter has a cross-sectional shape corresponding to the light transmitting pattern, and
the central portion of the first color filter overlaps the light transmitting pattern.

5. The display device of claim 4, wherein in at least two of the emission areas, thicknesses of the light transmitting pattern are different.

6. The display device of claim 3, further comprising:
a first emission area of the emission areas including a light transmitting pattern disposed under the first color filter; and
a second emission area of the emission areas includes a second color filter disposed in an opening of the light transmitting pattern.

7. The display device of claim 6, wherein a color filter disposed in an emission area corresponding to an opening in the light transmitting pattern among the emission areas has a concave cross-sectional shape in which a height of a central portion disposed in each emission area is lower than a height of an edge portion.

8. The display device of claim 1, wherein the emission areas comprise:
a first emission area in which a first light emitting element emitting light of a first color and a first color filter transmitting the light of the first color are disposed;
a second emission area in which a second light emitting element emitting light of a second color and a second color filter transmitting the light of the second color are disposed; and
a third emission area in which a third light emitting element emitting light of a third color is disposed.

9. The display device of claim 8, wherein a size of the second emission area is smaller than a size of each of the first emission area and the third emission area.

10. The display device of claim 9, further comprising a light transmitting pattern disposed under the second color filter in the second emission area, wherein the second color filter has a convex cross-sectional shape corresponding to the light transmitting pattern.

11. The display device of claim 10, wherein the light transmitting pattern comprises a first pattern disposed under the first color filter in the first emission area and a second pattern disposed under the second color filter in the second emission area, and the first color filter and the second color filter each have a convex cross-sectional shape corresponding to the first pattern and the second pattern.

12. The display device of claim 11, wherein a thickness of the first pattern is less than a thickness of the second pattern.

13. The display device of claim 11, further comprising a third color filter disposed in the third emission area and transmitting the light of the third color,
wherein the light transmitting pattern further comprises a third pattern disposed under the third color filter in the third emission area, and
the third color filter has a convex cross-sectional shape corresponding to the third pattern.

14. The display device of claim 13, wherein at least two of the first pattern, the second pattern and the third pattern have different thicknesses.

15. The display device of claim 11, further comprising a third color filter disposed in the third emission area and transmitting the light of the third color, wherein the light transmitting pattern includes an opening in the third emission area, and the third color filter has a concave cross-sectional shape in which a height of a central portion disposed in the third emission area is lower than a height of an edge portion.

16. The display device of claim 3, further comprising a touch sensing layer comprising a touch electrode and an insulating layer, wherein the touch sensing layer is disposed between a first color filter layer comprising the color filters and the light emitting element layer.

17. The display device of claim 16, wherein the light transmitting pattern is integral with the insulating layer, and
the insulating layer partially protrudes under the first color filter to form the light transmitting pattern.

18. The display device of claim 1, wherein the first color filter comprises:
a lower layer portion disposed in an emission area of the emission areas and a non-emission area surrounding the emission area; and
an upper layer portion disposed on a portion of the lower layer portion in the emission area and protruding in a height direction from the lower layer portion.

19. The display device of claim 18, further comprising a light blocking layer disposed in the non-emission area on a light emitting element layer comprising the light emitting elements,
wherein the upper layer portion of the first color filter is surrounded by the light blocking layer and spaced apart from the light blocking layer in plan view.

20. An electronic device including a display device, the display device comprising:
light emitting elements arranged in emission areas of sub-pixels; and
color filters disposed on the light emitting elements, and overlapping the emission areas and a non-emission area around the emission areas,
wherein a first color filter of the color filters has a convex cross-sectional shape including a central portion disposed in its emission area and an edge portion, the central portion protruding higher than a height of the edge portion, and
at least two of the color filters have different cross-sectional shapes.
